(19) United States
(12) Patent Application Publication
(10) Pub. No.: US 2015/0301412 A1
(43) Pub. Date: Oct. 22, 2015

(54) LIQUID CRYSTAL DISPLAY DEVICE

(71) Applicant: Sharp Kabushiki Kaisha, Osaka-shi, Osaka (JP)

(72) Inventors: Yosuke IWATA, Osaka (JP); Mitsuhiro MURATA, Osaka (JP); Kouhei TANAKA, Osaka (JP); Akihito JINDA, Osaka (JP)

(73) Assignee: Sharp Kabushiki Kaisha, Osaka (JP)

(21) Appl. No.: 14/437,659

(22) PCT Filed: Oct. 18, 2013
(86) PCT No.: PCT/JP2013/078265

§ 371 Date: Apr. 22, 2015

(30) Foreign Application Priority Data
Oct. 23, 2012 (JP) 2012-234063

(51) Int. Cl. G02F 1/1343; H01L 29/24; H01L 29/786

(52) U.S. Cl. CPC G02F 1/134309; G02F 1/13439; H01L 29/7869; H01L 29/24

(57) ABSTRACT

The present invention provides an ON-ON switching mode liquid crystal display device capable of enabling multi-V-T within a pixel and adequately improving viewing angle properties while adequately preventing any decrease in the liquid crystal molecule rising response rate. The liquid crystal display device is provided with at least a first substrate, a second substrate facing the first substrate, and a liquid crystal layer enclosed between the second and first substrates; wherein the first substrate has a first electrode, a second electrode and a third electrode having an opening, the second substrate has a planar fourth electrode, the first electrode and second electrode are a pair of comb-shaped electrodes that include a plurality of fingers on the liquid crystal layer side of the third electrode, and when viewing the main surface of the substrate from above, the ratio of overlap between the third electrode and a region between a finger of the first electrode and an adjacent finger of the second electrode is different within a pixel.

### TECHNICAL FIELD

The present invention relates to a liquid crystal display device. More particularly, the present invention relates to a liquid crystal display device having a three-layer electrode structure for controlling the alignment of liquid crystal molecules in the rising and falling directions by means of an electric field.

### BACKGROUND ART

Liquid crystal display devices are constructed from liquid crystal display elements enclosed between a pair of glass substrates or the like, and by utilizing the advantages of thin profile, low weight and low power consumption, these devices have become an essential part of daily life and business in mobile usage, monitors, televisions and so forth. In recent years the application of liquid crystal display devices has expanded to e-books, photo frames, IAs (industrial appliances), PCs (personal computers), tablet PCs, smartphones, etc. For these uses, various modes of liquid crystal display device having different electrode arrangements and substrate designs to alter the optical properties of the liquid crystal layer have been investigated, such as those described below.

A liquid crystal display device has been disclosed that contains p-type nematic liquid crystal enclosed between two substrates, at least one of which is transparent, the liquid crystal display device being characterized in that the p-type nematic liquid crystal is aligned perpendicularly with respect to the surfaces of the two substrates when no voltage is applied, and at least one of the two substrates has comb-shaped electrodes having an electrode width L and electrode spacing S that satisfy the relationship (S+1.7)/(S+L)≧0.7 (see Patent Document 1, for example).

A liquid crystal display panel has been disclosed that includes a pair of substrates and a liquid crystal layer sealed between the substrates, the liquid crystal display panel being characterized in that at least one of the pair of substrates has a pixel electrode, the same substrate has a common electrode and the other substrate has an opposite electrode, and when viewing the main surface of the substrate from above, the opposite electrode overlaps with the region between the pixel electrode and one of the adjacent common electrodes, and overlaps with the region between the pixel electrode and the other adjacent common electrode, and is separated by ≧2 μm from the edge of the pixel electrode (see Patent Document 2, for example).

### RELATED ART DOCUMENTS

### Patent Documents

Patent Document 1: WO 2009/157271

Patent Document 2: WO 2012/066988

### SUMMARY OF THE INVENTION

### Problems to be Solved by the Invention

It is therefore desirable to improve the viewing angle properties, for example, in a liquid crystal display device by varying the optical properties (voltage-transmittance properties (below also referred to as “V-T properties”), for example) of the liquid crystal layer based on the electrode arrangement, etc. However, in a liquid crystal display device that has a three-layer electrode structure for controlling the alignment of liquid crystal molecules in the rising and falling directions by means of an electric field, and that performs vertical field ON-horizontal field ON (the vertical field being perpendicular and the horizontal field being parallel to the main surface of the substrate) ON switching, there was scope for devising a means of enabling different V-T properties within a pixel and improving viewing angle properties while adequately preventing reduction in the liquid crystal molecule rising response rate. Hereinafter, this ON switching is also referred to as the “ON-ON switching mode”, and the different V-T properties are also referred to as “multi-V-T”.

The liquid crystal display panel 2525 provided in an ON-ON switching mode liquid crystal display device as shown in FIG. 27 is described below as an example. FIG. 27 is a cross-sectional schematic diagram showing a liquid crystal display panel provided in a conventional ON-ON switching mode liquid crystal display device.

The liquid crystal display panel 2525 is provided with a lower substrate 2523, which is an active matrix substrate provided with thin-film transistor elements, for example (below also referred to as ‘TFT substrate’), an upper substrate 2524, which is a color filter substrate, for example (below also referred to as ‘CF substrate’), that faces the lower substrate 2523, and a liquid crystal layer 2521 enclosed by the lower substrate 2523 and upper substrate 2524.

Liquid crystal molecules 2522 in the liquid crystal layer 2521 are aligned perpendicularly to the main surface of the substrate when no voltage is applied.

The lower substrate 2523 has a glass substrate 2518a, a planar lower electrode 2516 formed on the glass substrate 2518a on the liquid crystal layer 2521 side of the glass substrate 2518a, an insulating layer 2519a formed on the lower electrode 2516 on the liquid crystal layer 2521 side of the lower electrode 2516, and a pair of comb-shaped electrodes 2515a and 2515b formed on the insulating layer 2519a on the liquid crystal layer 2521 side of the insulating layer 2519a.

The upper substrate 2524 has a glass substrate 2518b, an opposite electrode 2520 formed on the glass substrate 2518b on the liquid crystal layer 2521 side of the glass substrate 2518b, and an insulating layer 2519b formed on the opposite electrode 2520 on the liquid crystal layer 2521 side of the opposite electrode 2520. A color filter layer (not shown) and black matrix (not shown) may also be formed between the glass substrate 2518b and the opposite electrode 2520.

FIG. 28 is a graph showing the V-T properties of a conventional ON-ON switching mode liquid crystal display device. Here, in the liquid crystal display panel 2525 provided in a conventional ON-ON switching mode liquid crystal display device as shown in FIG. 27, if the lower electrode 2516 is planar and formed on substantially the entire surface (solid) and the spacing S between the comb-shaped electrodes 2515a and 2515b (comb-shaped electrode spacing) is constant, the V-T properties between all comb-shaped electrodes within a pixel will uniformly adopt the pattern shown in FIG. 28, and consequently multi-V-T cannot be enabled within the pixel and adequate viewing angle properties cannot be obtained.

The aforementioned Patent Document 1 discloses a liquid crystal display device that is capable of achieving superior wide viewing angle properties and rapid response at the same time, and can perform display by means of a display format that does not require an initial bend transition operation. Specifically, disclosed is a liquid crystal display device that enables multi-V-T and improves viewing angle properties by providing two regions with different comb-shaped electrode spacings S within a single pixel in a TBA (transverse bend alignment) mode liquid crystal display device. However, the invention according to Patent Document 1 does not fully solve the aforementioned problems, because if the comb-shaped electrode spacing S becomes large, the horizontal field between the comb-shaped electrodes will weaken, resulting in a slower rising response rate of the liquid crystal molecules.

In addition, Patent Document 2 discloses a liquid crystal display panel and liquid crystal display device that can adequately improve transmittance by specifying the positional relationship between an opposite electrode and a pixel electrode. However, the invention according to Patent Document 2 does not enable multi-V-T within a pixel, and therefore does not fully solve the aforementioned problems.

In light of the aforementioned situation, the objective of the present invention is to provide an ON-ON switching mode liquid crystal display device capable of enabling multi-V-T within a pixel and adequately improving viewing angle properties while adequately preventing any decrease in the liquid crystal molecule rising response rate.

### Means for Solving the Problem

The inventors of the present invention focused on the provision of an opening in the lower electrode after conducting various investigations into ON-ON switching mode liquid crystal display devices capable of enabling multi-V-T within a pixel and adequately improving viewing angle properties while adequately preventing any decrease in the liquid crystal molecule rising response rate. The inventors then discovered that it is possible to enable multi-V-T within a pixel and improve viewing angle properties in a structure in which the lower electrode has an opening, because V-T properties in the region where the lower electrode is present (non-open portion) differ from V-T properties in the region where the lower electrode is not present (opening). As a result, the inventors arrived at the present invention after realizing that the aforementioned problems could be solved while adequately preventing any decrease in the liquid crystal molecule rising response rate.

Specifically, one aspect of the present invention is a liquid crystal display device, including at least: a first substrate; a second substrate facing the first substrate; and a liquid crystal layer enclosed between the first substrate and the second substrate; wherein the first substrate has a first electrode, a second electrode, and a third electrode, wherein the second substrate has a fourth electrode, wherein the first electrode and the second electrode are a pair of comb-shaped electrodes that include a plurality of fingers and are provided on a liquid crystal layer side of the third electrode, wherein the third electrode has an opening, wherein the fourth electrode is a planar electrode, and wherein, in a plan view of a main surface of either substrate, an amount of overlap between the third electrode and a region between a finger of the first electrode and a finger adjacent thereto of the second electrode differs within a pixel.

Furthermore, in one aspect of the liquid crystal display device of the present invention, an electrode spacing between the first and second electrodes may be substantially equal within a pixel. “An electrode spacing between the first and second electrodes may be substantially equal within a pixel” may refer to electrode spacing that is equal within the technical field of the present invention, and includes aspects in which the electrode spacing is substantially equal.

In addition, “a region between a finger of the first electrode and an adjacent finger of the second electrode” is, for example, a region AR1 between the widthwise center of a finger of a left comb-shaped electrode 15a and the widthwise center of a finger of a comb-shaped electrode 15b, and a region AR2 between the widthwise center of a finger of a right comb-shaped electrode 15a and the widthwise center of a finger of the comb-shaped electrode 15b, in a liquid crystal display panel 25 provided in the liquid crystal display device shown in FIG. 2. Also, “a proportion of overlap between the third electrode and a region [ . . . ] is different within a pixel” means that the proportion of overlap differs within a pixel such that when viewing the main surface of a substrate from above, the region AR1 overlaps with a lower electrode 16, and the region AR2 does not overlap with the lower electrode 16, for example. The comb-shaped electrodes 15a and 15b and lower electrode 16 correspond respectively to the aforementioned first electrode, second electrode and third electrode of one aspect of the present invention.

As long as the components described above are included as essential components, the liquid crystal display device according to the present invention is not particularly limited by other components, and other configurations normally used in liquid crystal display devices can be suitably applied.

### Effects of the Invention

According to one aspect of the present invention, it is possible to provide an ON-ON switching mode liquid crystal display device capable of enabling multi-V-T within a pixel and adequately improving viewing angle properties while adequately preventing any decrease in the liquid crystal molecule rising response rate.

### BRIEF DESCRIPTION OF THE DRAWINGS

FIG. 1 is a schematic plan view of a pixel of a liquid crystal display panel provided in a liquid crystal display device according to Embodiment 1.

FIG. 2 is a schematic cross-sectional view showing the section corresponding to the line a-a′ in FIG. 1.

FIG. 3 is a graph showing V-T properties in each region in a liquid crystal display device according to Working Examples 1 and 2.

FIG. 4 is a graph showing V-T properties in a liquid crystal display device according to Working Examples 1 and 2.

FIG. 5 shows director distribution and transmittance distribution in a liquid crystal display device according to Working Example 1.

FIG. 6 shows gamma shift properties at direction angle 0°-180°, deflection angle 60° in a liquid crystal display device according to Working Example 1 and Comparison Example 1-1.

FIG. 7 shows gamma shift properties at direction angle 45°-225°, deflection angle 60° in a liquid crystal display device according to Working Example 1 and Comparison Example 1-1.

FIG. 8 is a graph showing the liquid crystal molecule rising response properties in a liquid crystal display device according to Working Examples 1 and 2 and Comparison Examples 1-1, 1-2 and 1-3.

FIG. 9 is a cross-sectional schematic diagram showing a liquid crystal display panel provided in a liquid crystal display device according to Embodiment 2.

FIG. 10 shows director distribution and transmittance distribution in a liquid crystal display device according to Working Example 2.

FIG. 11 shows gamma shift properties at direction angle 0°-180°, deflection angle 60° in a liquid crystal display device according to Working Example 2 and Comparison Example 1-1.

FIG. 12 shows gamma shift properties at direction angle 45°-225°, deflection angle 60° in a liquid crystal display device according to Working Example 2 and Comparison Example 1-1.

FIG. 13 is a graph showing the V-T properties in each region in a liquid crystal display device according to Working Examples 3 and 4.

FIG. 14 is a graph showing the V-T properties of a liquid crystal display device according to Working Examples 3 and 4.

FIG. 15 shows director distribution and transmittance distribution in a liquid crystal display device according to Working Example 3.

FIG. 16 shows gamma shift properties at direction angle 0°-180°, deflection angle 60° in a liquid crystal display device according to Working Examples 3 and 4 and Comparison Example 2.

FIG. 17 shows gamma shift properties at direction angle 45°-225°, deflection angle 60° in a liquid crystal display device according to Working Examples 3 and 4 and Comparison Example 2.

FIG. 18 shows director distribution and transmittance distribution in a liquid crystal display device according to Working Example 4.

FIG. 19 is a schematic plan view showing a pixel of a liquid crystal display panel provided in a liquid crystal display device according to Embodiment 5.

FIG. 20 is a schematic plan view showing a pixel of a liquid crystal display panel provided in a liquid crystal display device according to Embodiment 6.

FIG. 21 is a schematic plan view showing the space between an adjacent pair of comb-shaped electrodes in a pixel of a liquid crystal display panel provided in a liquid crystal display device according to Embodiment 7.

FIG. 22 is a schematic plan view showing the space between an adjacent pair of comb-shaped electrodes in a pixel when slits in the lower electrode are of a fixed width.

FIG. 23 is a schematic plan view showing a pixel of a liquid crystal display panel provided in a liquid crystal display device according to Comparison Aspect 1.

FIG. 24 is a schematic cross-sectional view showing the section corresponding to the line A-A′ in FIG. 23.

FIG. 25 shows director distribution and transmittance distribution in a liquid crystal display device according to Comparison Example 1-1.

FIG. 26 shows director distribution and transmittance distribution in a liquid crystal display device according to Comparison Example 2.

FIG. 27 is a cross-sectional schematic diagram showing a liquid crystal display panel provided in a conventional ON-ON switching mode liquid crystal display device.

FIG. 28 is a graph showing the V-T properties of a conventional ON-ON switching mode liquid crystal display device.

### DETAILED DESCRIPTION OF EMBODIMENTS

Other preferred aspects of the liquid crystal display device according to the present invention are described below. The various aspects of the liquid crystal display device according to the present invention can be suitably combined.

According to one aspect of the liquid crystal display device of the present invention, liquid crystal molecules contained in the liquid crystal layer may be aligned perpendicularly to the main surface of either substrate when no voltage is applied thereto.

This type of perpendicular alignment-type liquid crystal display device is advantageous for obtaining properties such as a wide viewing angle and high contrast. Therefore, if the liquid crystal display device of the present invention is a perpendicular alignment-type liquid crystal display device, it is possible to improve viewing angle properties by enabling multi-V-T properties within a pixel, and to achieve a wide viewing angle and high contrast, while adequately preventing any decrease in the liquid crystal molecule rising response rate. “When no voltage is applied” may refer to there being substantially no application of voltage in the technical field of the present invention. In addition, “aligned perpendicularly to the main surface of the substrate” may refer to being aligned vertically to the main surface of a substrate in the technical field of the present invention, and includes embodiments in which alignment is in a substantially vertical direction. Furthermore, “liquid crystal molecule rising” refers to the interval in which the display condition of a liquid crystal display device changes from a dark condition (black display) to a bright condition (white display).

According to one aspect of the liquid crystal display device of the present invention, the liquid crystal display device may include a first region and a second region within a pixel, the first region may be a region between a finger of the first electrode and a finger adjacent thereto of the second electrode, the region may entirely overlap the third electrode, the second region may be a region between a finger of the first electrode and a finger adjacent thereto of the second electrode, and the region does not need to overlap the third electrode, and an area ratio of the first region to the second region may be 1:1.

As a result, the electrode structure of the first region and second region is different, and therefore each region has different V-T properties, making it possible to enable multi-V-T within a pixel. Therefore the viewing angle properties of the liquid crystal display device can be improved. “Fingers of the [ . . . ] electrode” refers to the linear portions of a comb-shaped electrode, and portions having straight edges and provided with the same capability of generating an electric field as the linear portions, for example.

The area ratio of the first region and the second region is not particularly restricted and may be a value other than 1:1, as long as the effects of one aspect of the present invention can be achieved.

According to one aspect of the liquid crystal display device of the present invention, the liquid crystal display device may include a first region and a third region within a pixel, the first region may be a region between a finger of the first electrode and a finger adjacent thereto of the second electrode, the region may entirely overlap the third electrode, the third region may be a region between a finger of the first electrode and a finger adjacent thereto of the second electrode, the region may partially overlap the third electrode, and an area ratio of the first region to the third region may be 1:1.

As a result, the electrode structure of the first region and third region is different, and therefore each region has different V-T properties, making it possible to enable multi-V-T within a pixel. Therefore, viewing angle properties can be improved.

The area ratio of the first region and the third region is not particularly restricted and may be a value other than 1:1, as long as the effects of one aspect of the present invention can be achieved.

According to one aspect of the liquid crystal display device of the present invention, at least one of the first substrate and the second substrate may be provided with a thin-film transistor element, and the thin-film transistor element may include an oxide semiconductor.

The aforementioned oxide semiconductor is characterized by having higher mobility than a-Si (amorphous silicon) and small variation in properties. For this reason, a TFT containing an oxide semiconductor can operate at a faster rate and has a faster driving frequency than a TFT containing a-Si, occupies a smaller proportion of a single pixel, and is therefore preferable for driving high-definition next-generation display devices. Also, an oxide semiconductor film is formed by a more convenient process than a polycrystalline film and therefore has the advantage of also being suitable for devices that require a large area. Therefore, if the liquid crystal display device of the present invention is provided with a TFT containing an oxide semiconductor, it is possible to enable multi-V-T within a pixel and improve viewing angle properties while adequately preventing any decrease in the liquid crystal molecule rising response rate, and to achieve a higher aperture ratio and faster driving speed than in a liquid crystal display device provided with a TFT containing a-Si.

The structure of the aforementioned oxide semiconductor may also be IGZO (In—Ga—Zn—O) formed of indium (In), gallium (Ga), zinc (Zn) and oxygen (O), ITZO (In-Tin-Zn-O) formed of indium (In), tin (Tin), zinc (Zn) and oxygen (O), or IAZO (In—Al—Zn—O) formed of indium (In), aluminum (Al), zinc (Zn) and oxygen (O), for example.

According to one aspect of the liquid crystal display device of the present invention, the first and second electrodes, which are a pair of comb-shaped electrodes, may be formed from the same layer. The first and second electrodes, which are a pair of comb-shaped electrodes, may be formed on different layers as long as the effects of one aspect of the present invention can be achieved. Here, “the first and second electrodes, which are a pair of comb-shaped electrodes, may be formed on the same layer” means that each comb-shaped electrode is in contact with shared components (insulating layer and/or liquid crystal layer, for example) on the liquid crystal layer side and/or the side opposite the liquid crystal layer side.

According to one aspect of the liquid crystal display device of the present invention, the first substrate may further have an insulating layer, and the insulating layer may be on the side opposite the liquid crystal layer side of the first and second electrodes.

Here, a horizontal electric field (an electric field parallel to the main surface of a substrate) can be suitably generated between a pair of comb-shaped electrodes that include a plurality of fingers (between the first and second electrodes). “An electric field parallel to the main surface of a substrate” may refer to an electric field that is parallel to the main surface of a substrate in the technical field of the present invention, and includes embodiments in which an electric field is generated in a substantially horizontal direction.

Next, by means of the third electrode, which has an opening, and the fourth electrode, which is planar, a vertical electric field (an electric field perpendicular to the main surface of a substrate) can be suitably generated between the first substrate, which has the third electrode, and the second substrate, which has the fourth electrode. “An electric field perpendicular to the main surface of a substrate” may refer to an electric field that is vertical to the main surface of a substrate in the technical field of the present invention, and includes embodiments in which an electric field is generated in a substantially vertical direction. Also, when patterning the fourth electrode using a photomask, defects are unlikely to occur even if the photomask becomes misaligned.

It is therefore possible to suitably generate the horizontal and vertical electric fields described above.

According to one aspect of the liquid crystal display device of the present invention, liquid crystal molecules contained in the liquid crystal layer may have positive dielectric anisotropy.

Liquid crystal molecules having positive dielectric anisotropy can achieve a faster response time because the long axis of the liquid crystal molecules aligns along the electric force lines when voltage is applied, making alignment control easy.

According to one aspect of the liquid crystal display device of the present invention, liquid crystal molecules contained in the liquid crystal layer may have negative dielectric anisotropy. As a result, transmittance can be further improved.

Therefore, from the perspective of fast response, it is preferable if liquid crystal molecules contained in the liquid crystal layer are substantially constituted by liquid crystal molecules having positive dielectric anisotropy, and in terms of transmittance, it is preferable if liquid crystal molecules contained in the liquid crystal layer are substantially constituted by liquid crystal molecules having negative dielectric anisotropy.

According to one aspect of the liquid crystal display device of the present invention, the liquid crystal display device may further have a polarizing plate, and this polarizing plate may be a linear polarizing plate. This makes it possible to further improve viewing angle properties.

A linear polarizing plate normally used in the technical field of the present invention can be used, there being no particular limitations on the type and structure of the linear polarizing plate.

In addition, according to another aspect of the liquid crystal display device of the present invention, the liquid crystal display device further has a polarizing plate, and this polarizing plate may be a circularly polarizing plate. This makes it possible to improve transmittance.

A circularly polarizing plate normally used in the technical field of the present invention can be used, there being no particular limitations on the type and structure of the circularly polarizing plate.

According to one aspect of the liquid crystal display device of the present invention, the liquid crystal display device may be one which includes a second region and a third region within a pixel, the second region is the region between a finger of the first electrode and an adjacent finger of the second electrode, this region and the third electrode do not overlap, the third region is the region between a finger of the first electrode and an adjacent finger of the second electrode, part of this region and the third electrode overlap, and an area ratio of the second region and third region is 1:1.

As a result, the electrode structure of the second region and third region is different, and therefore each region has different V-T properties, making it possible to enable multi-V-T within a pixel. Therefore, viewing angle properties can be improved.

The area ratio of the second region and the third region is not particularly restricted and may be a value other than 1:1, as long as the effects of one aspect of the present invention can be achieved.

According to one aspect of the liquid crystal display device of the present invention, the width of the opening of the third electrode in the region between a finger of the first electrode and an adjacent finger of the second electrode may vary along the length of the second electrode.

As a result, the electrode structure is different in regions of the third electrode with different widths of the opening, and therefore each region has different V-T properties, making it possible to enable multi-V-T within a pixel. Therefore, viewing angle properties can be improved.

Each of the above-described aspects can be appropriately combined insofar as the spirit of the present invention is not departed from.

Through the embodiments below, the present invention is described in further detail below with reference to the drawings, but the invention is not limited to these embodiments.

The liquid crystal display device has a basic structure that generally includes a liquid crystal display panel and members such as a light source. The basic structure of the liquid crystal display panel includes a pair of substrates on which transparent electrodes, alignment film and so forth (a TFT substrate and CF substrate, for example) are formed, a liquid crystal layer enclosed between the two substrates, and spacers for maintaining a gap between the two substrates, the two substrates being stuck together using a sealing material or the like. In addition, the liquid crystal display device can be suitably provided with other members (external circuits, for example) that are provided in normal liquid crystal display devices.

### Embodiment 1

### The Area Ratio of the First Region and Second Region is 1:1 and a Linear Polarizing Plate is Used

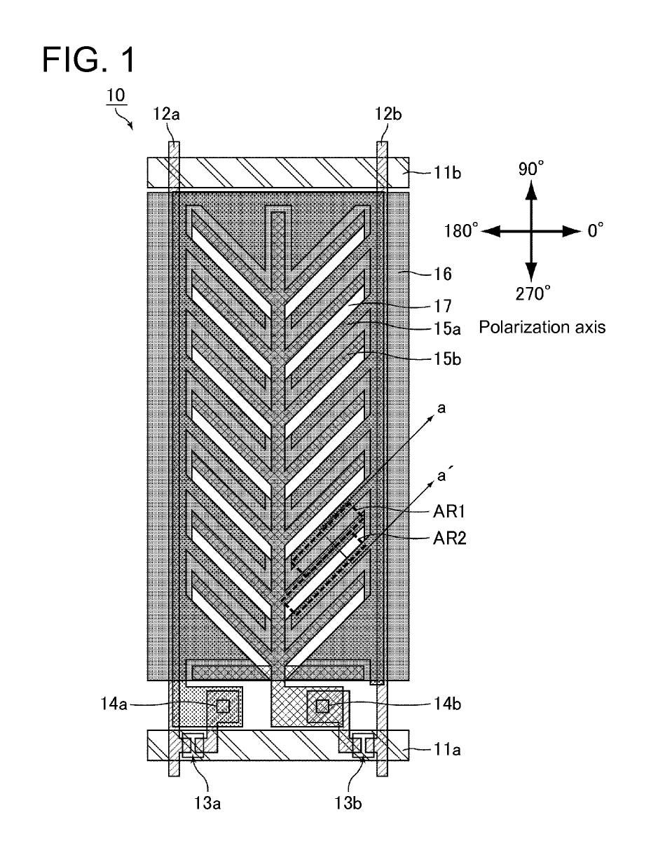

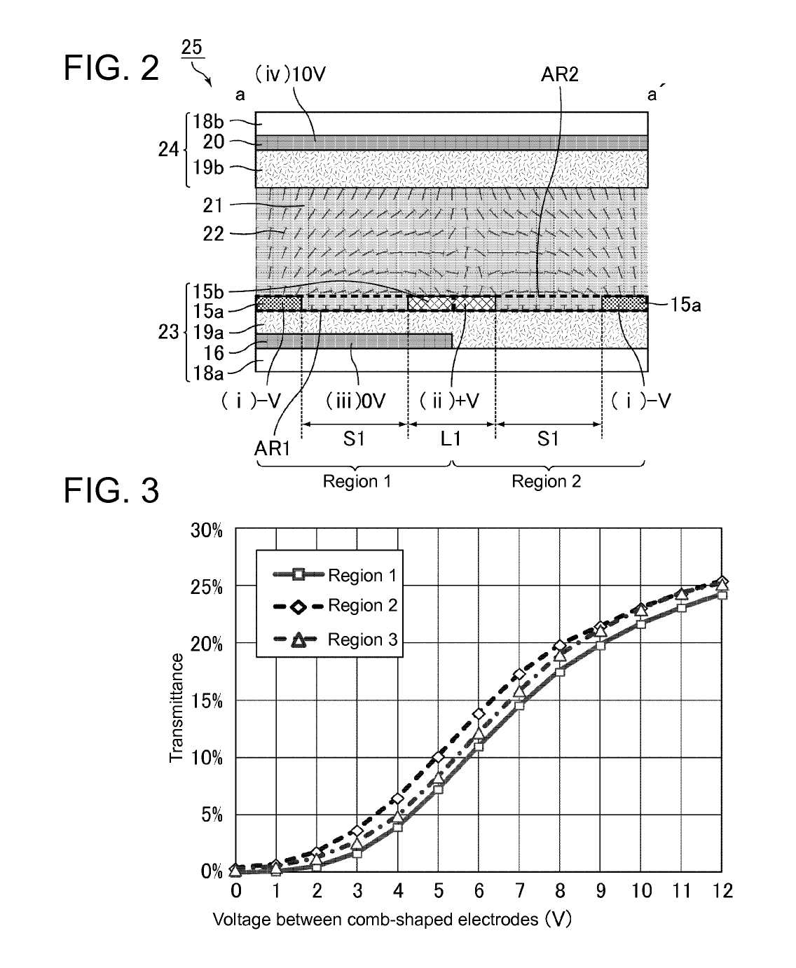

The liquid crystal display device according to Embodiment 1 is described with reference to FIGS. 1 and 2.

FIG. 1 is a schematic plan view of a pixel of a liquid crystal display panel provided in a liquid crystal display device according to Embodiment 1. In the liquid crystal display device according to Embodiment 1, within a pixel 10 and at a timing chosen by a gate bus line 11a, a voltage supplied from a source bus line 12a is applied through a TFT 13a and a contact hole 14a to a comb-shaped electrode 15a, which is one of a pair of comb-shaped electrodes that drive a liquid crystal layer, and a voltage supplied from a source bus line 12b is applied through a TFT 13b and a contact hole 14b to a comb-shaped electrode 15b, which is the other of the pair of comb-shaped electrodes. Also, a plurality of mutually parallel slits 17 are formed in a lower electrode 16. In FIG. 1, the comb-shaped electrodes 15a and 15b and the slits 17 in the lower electrode 16 have a slanting shape, and the pixel 10 has a rectangular shape, but the form of these components are not limited to these shapes, as long as the effects of one aspect of the present invention can be achieved. Also, the slits 17 correspond to the openings in the third electrode in one aspect of the present invention.

FIG. 2 is a schematic cross-sectional view showing the section corresponding to the line a-a′ in FIG. 1. The basic structure of the liquid crystal display panel 25 provided in the liquid crystal display device of Embodiment 1 includes a lower substrate 23, an upper substrate 24, and a liquid crystal layer 21 enclosed between the two substrates. Liquid crystal molecules 22 contained in the liquid crystal layer 21 have positive dielectric anisotropy (Δ∈>0). There is no particular limit on the thickness of the liquid crystal layer 21, but it is preferable that the thickness be ≧2 μm and ≦6 μm. Also, an alignment film (not shown) is formed on the liquid crystal layer 21 sides of the lower substrate 23 and the upper substrate 24 respectively, and this alignment film may be an organic alignment film or an inorganic alignment film, as long as the alignment film is a perpendicular alignment film that causes liquid crystal molecules to align in a direction vertical to the main surface of the substrate when a voltage is not applied. The lower substrate 23 and upper substrate 24 correspond respectively to the first substrate and second substrate of one aspect of the present invention.

In the liquid crystal display device according to Embodiment 1, the lower substrate 23 has a glass substrate 18a, a lower electrode 16 formed on part of the glass substrate 18a, on the liquid crystal layer 21 side of the glass substrate 18a, an insulating layer 19a formed on the lower electrode 16 and part of the glass substrate 18a, on the liquid crystal layer 21 sides of the lower electrode 16 and the glass substrate 18a, and the pair of comb-shaped electrodes 15a and 15b, formed on the insulating layer 19a, on the liquid crystal layer 21 side of the insulating layer 19a. Here, the lower electrode 16 and comb-shaped electrodes 15a and 15b are transparent electrodes such as electrodes of ITO (indium tin oxide) or IZO (indium zinc oxide), for example. Also, the comb-shaped electrodes 15a and 15b are formed on the same layer. Here, as shown in FIG. 2, Embodiment 1 is an embodiment in which, when region 1 is defined as the region of overlap between the lower electrode 16 and the whole of a region between a finger of the left comb-shaped electrode 15a and a finger of the comb-shaped electrode 15b, which are a mutually adjacent pair, and region 2 is defined as the region of non-overlap between the lower electrode 16 and a region between a finger of the right comb-shaped electrode 15a and a finger of the adjacent comb-shaped electrode 15b, region 1 and region 2 are arranged so as to alternate consecutively, and the area ratio of region 1 and region 2 is 1:1. The comb-shaped electrodes 15a and 15b correspond respectively to the first electrode and second electrode of one aspect of the present invention. The lower electrode 16 corresponds to the third electrode of one aspect of the present invention. In addition, region 1 and region 2 correspond respectively to the aforementioned first region and second region in one aspect of the present invention.

Here, the insulating layer 19a may be either an organic insulating film or an inorganic insulating film. There is no particular limit on the transmittance of the insulating layer 19a, but it is preferable that the transmittance be ≧2 and ≦10. Also, there is no particular limit on the thickness of the insulating layer 19a, but it is preferable that the thickness be ≧0.1 μm and ≦4 μm.

Here, as shown in FIG. 2, an electrode width L1 of the comb-shaped electrode 15b has no particular limitations, but is preferably ≧1 μm and ≦5 μm. The electrode width (not shown) of the comb-shaped electrode 15a is equal to the electrode width L1 of the comb-shaped electrode 15b. Also, the electrode spacing S1 between the comb-shaped electrodes 15a and 15b may be substantially identical within a pixel, and may also be substantially identical between pixels. The electrode spacing S1 between the comb-shaped electrodes 15a and 15b has no particular limitations as long as the electrode spacing S1 is substantially identical within a pixel, but a preferable electrode spacing S1 is ≧1 μm and ≦10 μm.

In the liquid crystal display device according to Embodiment 1, the upper substrate 24 has a glass substrate 18b, a planar opposite electrode 20 formed on the glass substrate 18b on a liquid crystal layer 21 side of the glass substrate 18b, and an insulating layer 19b formed on the opposite electrode 20, on the liquid crystal layer 21 side of the opposite electrode 20. The insulating layer 19b may be omitted. Here, the opposite electrode 20 is a transparent electrode of IZO or the like, for example. The opposite electrode 20 corresponds to the fourth electrode of one aspect of the present invention.

Here, the insulating layer 19b may be either an organic insulating film or an inorganic insulating film. There is no particular limit on the transmittance of the insulating layer 19b, but it is preferable that the transmittance be ≧2 and ≦10. Also, there is no particular limit on the thickness of the insulating layer 19b, but it is preferable that the thickness be ≧0.1 μm and ≦4 μm.

The liquid crystal display panel 25 provided in the liquid crystal display device according to Embodiment 1 further has a pair of linear polarizing plates (not shown) on the glass substrates 18a and 18b, on the side opposite the liquid crystal layer 18 side.

In the liquid crystal display device according to Embodiment 1, constant generation of an electric field is maintained in the liquid crystal layer 21 by generation of a fixed potential difference between the lower electrode 16 and the opposite electrode 20. A potential difference is then generated by applying a reversed polarity voltage between the comb-shaped electrodes 15a and 15b, and the strength of the horizontal electric field is controlled by varying the potential difference between the comb-shaped electrodes 15a and 15b, thereby producing a display having gradation.

In FIG. 2, (i), (ii), (iii) and (iv) are, respectively, the potential of the comb-shaped electrode 15a, the potential of the comb-shaped electrode 15b, the potential of the lower electrode 16 and the potential of the opposite electrode 20.

Apart from the above description, the liquid crystal display device according to Embodiment 1 can also be suitably provided with members (external circuits, for example) that are provided in normal liquid crystal display devices. The same applies to the embodiments described below.

Manufactured working examples of the liquid crystal display device according to Embodiment 1 are described below.

### Working Example 1

In Working Example 1, the liquid crystal molecules 22 have positive dielectric anisotropy, the dielectric anisotropy Δ∈ is 18 and the refractive-index anisotropy Δn is 0.12. The thickness of the liquid crystal layer 21 is 3.2 μm. The insulating layer 19a has a transmittance of 7 and a thickness of 0.3 μm. The insulating layer 19b has a transmittance of 4 and a thickness of 1.5 μm. The electrode width L1 of the comb-shaped electrodes 15a and 15b is 2.5 μm. The electrode spacing S1 between the comb-shaped electrodes 15a and 15b is 3 μm, and the spacing of each comb-shaped electrode within a pixel is substantially identical. The spacing of the comb-shaped electrodes being substantially equal means that it is preferable if the electrode spacing between comb-shaped electrodes 15a and 15b differs by ≦0.5 μm. A more preferable difference is ≦0.25 μm.

In Working Example 1, as shown in FIG. 2, the comb-shaped electrode 15a has a potential (i) of −V[V], the comb-shaped electrode 15b has a potential (ii) of +V[V], the lower electrode 16 has a potential (iii) of 0[V] and the opposite electrode 20 has a potential (iv) of 10[V] (above, [V] is the unit). Also, the lower substrate 23 is a TFT substrate and the upper substrate 24 is a CF substrate.

V-T properties were measured in region 1 and region 2 of the liquid crystal display device according to Working Example 1 using the above-described conditions. Gamma shift related to V-T properties and viewing angle properties and the liquid crystal molecule rising response properties of the liquid crystal display device according to Working Example 1 were also measured. The results are described below.

FIG. 3 is a graph showing V-T properties in each region in the liquid crystal display device according to Working Examples 1 and 2. The horizontal axis shows voltage between comb-shaped electrodes and the vertical axis shows transmittance. Here, the voltage between comb-shaped electrodes refers to the potential difference between the comb-shaped electrodes 15a and 15b, and is equivalent to 2V[V]. ‘Region 3’ in FIG. 3 is described below in Working Example 2.

As can be seen in FIG. 3, the V-T properties in region 1 are characterized by more of a shift to the high voltage side than the V-T properties in region 2, showing that the V-T properties in region 1 differ from the V-T properties in region 2. It is thus apparent that the liquid crystal display device of Working Example 1 has two different V-T properties, as described above, and has therefore enabled multi-V-T within the aforementioned pixel 10.

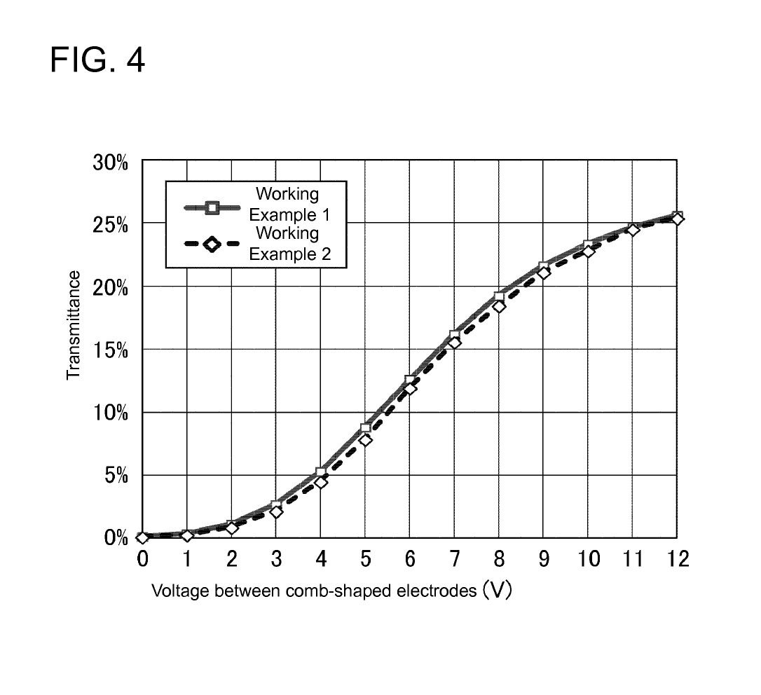

FIG. 4 is a graph showing V-T properties in a liquid crystal display device according to Working Examples 1 and 2. The horizontal axis shows voltage between comb-shaped electrodes and the vertical axis shows transmittance. Here, as in FIG. 3, the voltage between comb-shaped electrodes is equivalent to 2V[V]. ‘Working Example 2’ in FIG. 4 is described below in Working Example 2.

As shown in FIG. 4, the V-T properties of the liquid crystal display device according to Working Example 1 are a synthesis of the V-T properties in region 1 and the V-T properties in region 2.

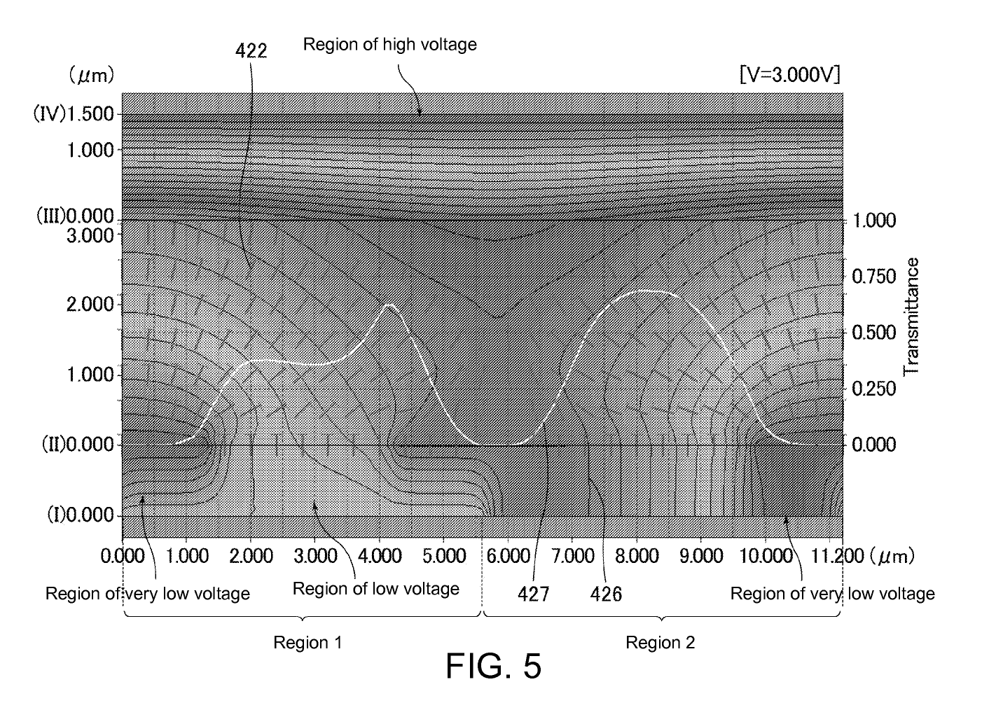

FIG. 5 shows director distribution and transmittance distribution in the liquid crystal display device according to Working Example 1. FIG. 5 shows directors 422, electric field distribution (equipotential lines) 426 and transmittance distribution 427 when the voltage between the comb-shaped electrodes 15a and 15b is 6[V] (corresponding to V=3.00[V] shown in FIG. 3).

The relationships between the values on the horizontal axis and left vertical axis in FIG. 5 and the positions of the parts shown in FIG. 2 are described below. In the horizontal axis in FIG. 5, the range of 0.000 μm to about 1.300 μm is the region where the left-side comb-shaped electrode 15a is present, the range of about 1.300 μm to about 4.300 μm is the region where neither the comb-shaped electrode 15a nor the comb-shaped electrode 15b is present, the range of about 4.300 μm to about 6.900 μm is the region where the comb-shaped electrode 15b is present, the range of about 6.900 μm to about 9.900 μm is the region where neither the comb-shaped electrode 15b nor the comb-shaped electrode 15a is present, the range of about 9.900 μm to 11.200 μm is the region where the right-side comb-shaped electrode 15a is present, the range of 0.000 μm to about 5.600 μm is the region where the lower electrode 16 is present, region 1 is the range of 0.000 μm to about 5.600 μm, and region 2 is the range of about 5.600 μm to 11.200 μm. On the left vertical axis in FIG. 5, (I) 0.000 μm is the interface between the glass substrate 18a and the insulating layer 19a, (II) 0.000 μm is the interface between the insulating layer 19a and the liquid crystal layer 21, (III) 0.000 μm is the interface between the liquid crystal layer 21 and the insulating layer 19b, and (IV) 1.500 μm is the interface between the insulating layer 19b and the opposite electrode 20. The transmittance of the liquid crystal display device according to Working Example 1 shown in FIG. 4 is the transmittance measured in the region corresponding to the range 0.000 μm to 11.200 μm on the horizontal axis in FIG. 5.

As can be seen in FIG. 5, transmittance distribution in region 1 differs from transmittance distribution in region 2. It is therefore apparent that multi-V-T has been enabled within the pixel 10.

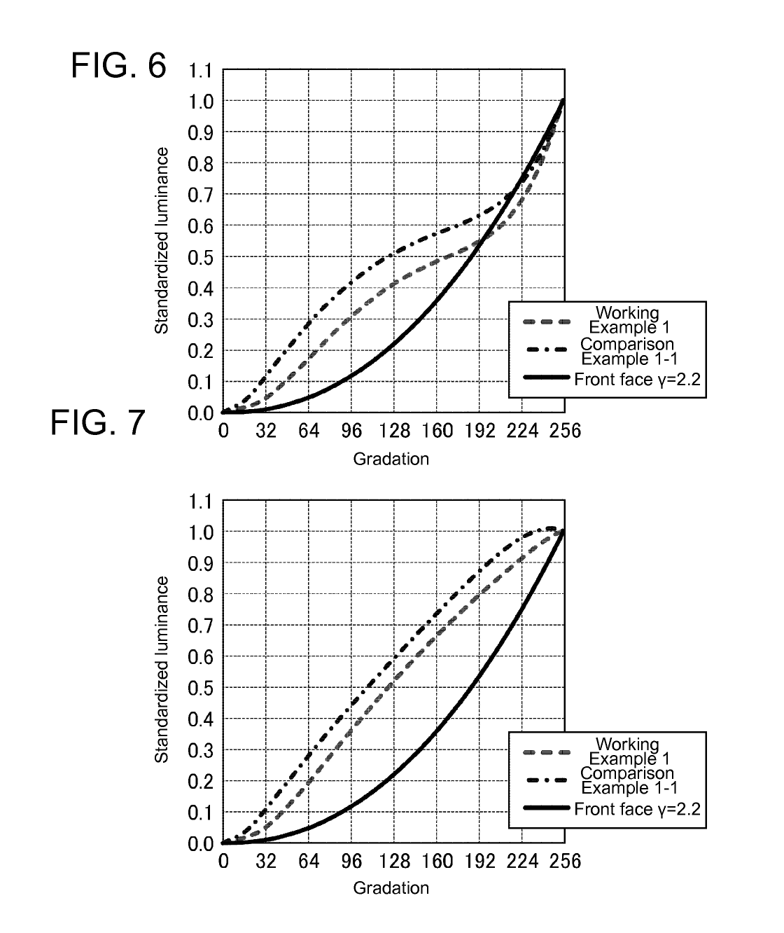

FIG. 6 shows gamma shift properties at direction angle 0°-180°, deflection angle 60° in the liquid crystal display device according to Working Example 1 and Comparison Example 1-1. FIG. 7 shows gamma shift properties at direction angle 45°-225°, deflection angle 60° in the liquid crystal display device according to Working Example 1 and Comparison Example 1-1. The horizontal axis shows gradation and the vertical axis shows the standardized luminance ratio. The standardized luminance ratio expresses the ratio of luminance of each gradation to luminance at maximum gradation (256 gradations). In FIGS. 6 and 7, ‘front face γ=2.2’ refers to the situation where observation is from the front of the liquid crystal display device, with adjustment so that γ=2.2. ‘Comparison Example 1-1’ is described below in Comparison Example 1-1. The two other curves (Working Example 1 curve and Comparison Example 1-1 curve) are curves obtained when confirming at an opposite angle 60° from the front. The direction angle is defined in the same way as shown in FIG. 1. Luminance in FIG. 6 is the mean value of luminance when confirmed at an opposite angle of 60° in the direction of angles 0° and 180°. Luminance in FIG. 7 is the mean value of luminance when confirmed at an opposite angle of 60° in the direction of angles 45° and 225°. Gamma shift, also called white crush, is a problem in which a curve for a particular direction has shifted in a direction with a higher luminance than the curve for the front direction. This causes the problem in which an image that looks normal when viewed from the front looks strange when viewed at an angle.

As can be seen in FIGS. 6 and 7, the curve for the liquid crystal display device according to Working Example 1 has shifted in a direction with a lower luminance than that of the liquid crystal display device according to Comparison Example 1-1 described below. In other words, the curve for the liquid crystal display device according to Working Example 1 has less gamma shift from the front than does the curve for the liquid crystal display device according to Comparison Example 1-1. It is therefore apparent that the viewing angle properties of the liquid crystal display device according to Working Example 1 are better than the viewing angle properties of the liquid crystal display device according to Comparison Example 1-1.

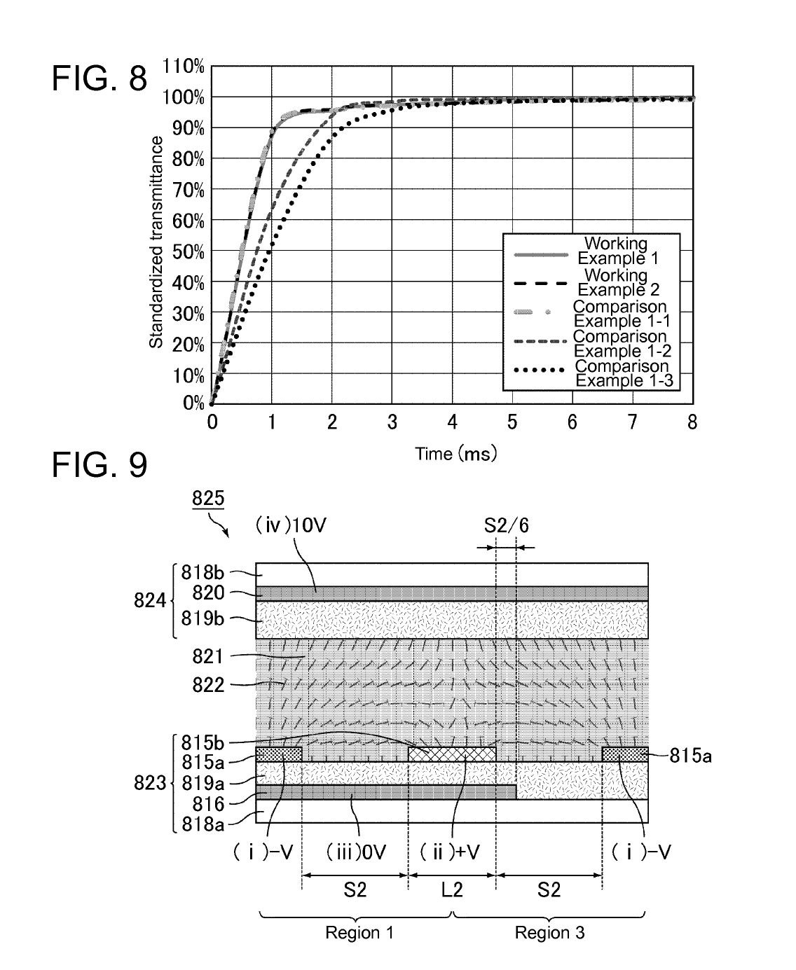

FIG. 8 is a graph showing the liquid crystal molecule rising response properties in the liquid crystal display device according to Working Examples 1 and 2 and Comparison Examples 1-1, 1-2 and 1-3. The horizontal axis shows time and the vertical axis shows standardized transmittance. Standardized transmittance expresses the ratio of transmittance at each time point to cumulative transmittance. Each curve is the curve for when the voltage between comb-shaped electrodes is set at 10[V] (when the voltage between the comb-shaped electrodes 15a and 15b is set at 10[V] in Working Example 1). ‘Working Example 2’, ‘Comparison Example 1-1’, ‘Comparison Example 1-2’ and ‘Comparison Example 1-3’ are described in detail below; the comb-shaped electrode spacing in ‘Working Example 2’ and ‘Comparison Example 1-1’ is 3 μm, the same as in Working Example 1, the comb-shaped electrode spacing in ‘Comparison Example 1-2’ is 5 μm, and the comb-shaped electrode spacing in ‘Comparison Example 1-3’ is 7 μm.

As can be seen in FIG. 8, the curve for the liquid crystal display device according to Working Example 1 shows the same response properties as the curves for the liquid crystal display device according to Working Example 2 and Comparison Example 1-1. It is thus apparent that the liquid crystal molecule rising response rate in the liquid crystal display device according to Working Example 1 is substantially equal to the liquid crystal molecule rising response rate in the liquid crystal display device according to Working Example 2 and Comparison Example 1-1 described below. This is because, by making the comb-shaped electrode spacing in the liquid crystal display device according to Working Example 1 equal to the comb-shaped electrode spacing in the liquid crystal display device according to Working Example 2 and Comparison Example 1-1, the electric field strength generated between the comb-shaped electrodes in the liquid crystal display device according to Working Example 1 becomes substantially equal to the electric field strength generated between the comb-shaped electrodes in the liquid crystal display device according to Working Example 2 and Comparison Example 1-1. Also, it is apparent that the liquid crystal molecule rising response rate in the liquid crystal display device according to Working Example 1 is faster than the liquid crystal molecule rising response rate in the liquid crystal display device according to Comparison Examples 1-2 and 1-3 described below. This is because, by making the comb-shaped electrode spacing in the liquid crystal display device according to Working Example 1 narrower than the comb-shaped electrode spacing in the liquid crystal display device according to Comparison Examples 1-2 and 1-3, the electric field strength generated between the comb-shaped electrodes in the liquid crystal display device according to Working Example 1 becomes stronger than the electric field strength generated between the comb-shaped electrodes in the liquid crystal display device according to Comparison Examples 1-2 and 1-3.

It is therefore apparent from the above description that the liquid crystal display device according to Working Example 1 is capable of enabling multi-V-T within a pixel and adequately improving viewing angle properties while adequately preventing any decrease in the liquid crystal molecule rising response rate.

### Embodiment 2

### The Area Ratio of the First Region and Third Region is 1:1 and a Linear Polarizing Plate is Used

The liquid crystal display device according to Embodiment 2 is described with reference to FIG. 9.

FIG. 9 is a cross-sectional schematic diagram showing a liquid crystal display panel provided in a liquid crystal display device according to Embodiment 2. The basic structure of the liquid crystal display panel 825 provided in the liquid crystal display device of Embodiment 2 includes a lower substrate 823, an upper substrate 824, and a liquid crystal layer 821 enclosed between the two substrates. The liquid crystal molecules 822 contained in the liquid crystal layer 821 have positive dielectric anisotropy (Δ∈>0). The lower substrate 823 and upper substrate 824 correspond respectively to the first and second substrates of one aspect of the present invention.

In the liquid crystal display device according to Embodiment 2, the lower substrate 823 has a glass substrate 818a, a lower electrode 816 formed on part of the glass substrate 818a, on the liquid crystal layer 821 side of the glass substrate 818a, an insulating layer 819a formed on the lower electrode 816 and part of the glass substrate 818a, on the liquid crystal layer 821 sides of the lower electrode 816 and the glass substrate 818a, and a pair of comb-shaped electrodes 815a and 815b, formed on the insulating layer 819a, on the liquid crystal layer 821 side of the insulating layer 819a. Also, the comb-shaped electrodes 815a and 815b are formed on the same layer. Here, as shown in FIG. 9, Embodiment 2 is an embodiment in which, when region 1 is defined as the region of overlap between the lower electrode 816 and the whole of the region between a finger of the left comb-shaped electrode 815a and a finger of the comb-shaped electrode 815b, which are a mutually adjacent pair, and region 3 is defined as the region of overlap between the lower electrode 816 and a region between a finger of the right comb-shaped electrode 815a and a finger of the comb-shaped electrode 15b, which are a mutually adjacent pair, region 1 and region 3 are arranged so as to alternate consecutively, and the area ratio of region 1 and region 3 is 1:1. Here, as shown in FIG. 9, if the electrode spacing between the comb-shaped electrodes 815a and 815b is S2 then the width of the cross-section of region 3 of Embodiment 1 is S2/6. The comb-shaped electrodes 815a and 815b correspond respectively to the first and second electrodes of one aspect of the present invention. The lower electrode 816 corresponds to the third electrode of one aspect of the present invention. In addition, regions 1 and 3 correspond respectively to the aforementioned first and third regions in one aspect of the present invention. It is preferable that the third region have a section that overlaps and a section that does not overlap with the third electrode in a direction perpendicular to the lengthwise direction of the fingers of each of the pair of comb-shaped electrodes (first and second electrodes).

In the liquid crystal display device according to embodiment 2, the upper substrate 824 has the glass substrate 818b, a planar opposite electrode 820 formed on the glass substrate 818b, on the liquid crystal layer 821 side of the glass substrate 818b, and the insulating layer 819b formed on the opposite electrode 820, on the liquid crystal layer 821 side of the opposite electrode 820. The insulating layer 819b may be omitted. The opposite electrode 820 corresponds to the fourth electrode of one aspect of the present invention.

The liquid crystal display panel 825 provided in the liquid crystal display device according to embodiment 2 further has a pair of linear polarizing plates (not shown) on the glass substrate 818a and the glass substrate 818b on the side opposite the liquid crystal layer 821 side.

In the liquid crystal display device according to Embodiment 2, constant generation of an electric field is maintained in the liquid crystal layer 821 by generation of a fixed potential difference between the lower electrode 816 and the opposite electrode 820. A potential difference is then generated by applying a reversed polarity voltage between the comb-shaped electrodes 815a and 815b, and the strength of the horizontal electric field is controlled by varying the potential difference between the comb-shaped electrodes 815a and 815b, thus producing a display having gradation.

In FIG. 9, (i), (ii), (iii) and (iv) are, respectively, the potential of the comb-shaped electrode 815a, the potential of the comb-shaped electrode 815b, the potential of the lower electrode 816 and the potential of the opposite electrode 820.

Other configurations of the liquid crystal display device according to Embodiment 2 are the same as the liquid crystal display device according to Embodiment 1.

Manufactured working examples of the liquid crystal display device according to Embodiment 2 are described below.

### Working Example 2

In Working Example 2, the liquid crystal molecules 822 have positive dielectric anisotropy, the dielectric anisotropy Δ∈ is 18 and the refractive-index anisotropy Δn is 0.12. The thickness of the liquid crystal layer 821 is 3.2 μm. The insulating layer 819a has a transmittance of 7 and a thickness of 0.3 μm. The insulating layer 819b has a transmittance of 4 and a thickness of 1.5 μm. The electrode width L2 of the comb-shaped electrode 815b is 2.5 μm and the electrode spacing S2 between the comb-shaped electrodes 815a and 815b is 3 μm. The electrode width (not shown) of the comb-shaped electrode 815a is equal to the electrode width L2 of the comb-shaped electrode 815b.

As shown in FIG. 9, in Working Example 2 the comb-shaped electrode 815a has a potential (i) of −V[V], the comb-shaped electrode 815b has a potential (ii) of +V[V], the lower electrode 816 has a potential (iii) of 0[V] and the opposite electrode 820 has a potential (iv) of 10[V] (above, [V] is the unit). Also, the lower substrate 823 is a TFT substrate and the upper substrate 824 is a CF substrate.

V-T properties were measured in region 2 and region 3 of the liquid crystal display device according to Working Example 2 using the above-described conditions. Gamma shift related to the V-T properties and viewing angle properties and the liquid crystal molecule rising response properties of the liquid crystal display device according to Working Example 2 were also measured. The results are described below.

The V-T properties in region 1 and region 3 in the liquid crystal display device according to Working Example 2 are described with reference to FIG. 3. As can be seen in FIG. 3, the V-T properties in region 1 are characterized by more of a shift to the high voltage side than the V-T properties in region 3, showing that the V-T properties in region 1 differ from V-T properties in region 3. It is thus apparent that the liquid crystal display device of Working Example 2 has two different V-T properties as described above and has therefore enabled multi-V-T within a pixel. It is also apparent that by forming region 3, it is possible to obtain V-T properties between the V-T properties in region 1 and the V-T properties in region 2.

The V-T properties in the liquid crystal display device according to Working Example 2 are described with reference to FIG. 4. As shown in FIG. 4, the V-T properties of the liquid crystal display device according to Working Example 2 are a synthesis of the V-T properties in region 1 and the V-T properties in region 3.

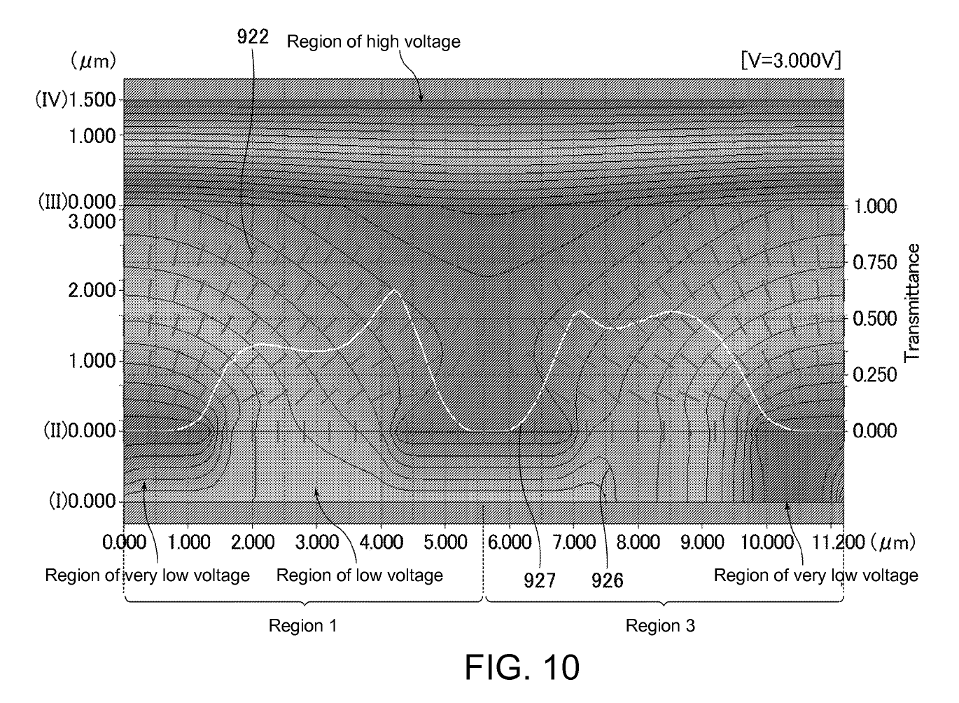

FIG. 10 shows director distribution and transmittance distribution in the liquid crystal display device according to Working Example 2. FIG. 10 shows directors 922, electric field distribution (equipotential lines) 926 and transmittance distribution 927 when the voltage between the comb-shaped electrodes 815a and 815b is 6[V] (corresponding to V=3.00[V] shown in FIG. 3).

The relationships between the values on the horizontal axis and the left vertical axis in FIG. 10 and the positions of the parts shown in FIG. 9 are described below. In the horizontal axis in FIG. 10, the range of 0.000 μm to about 1.300 μm is the region where the left-side comb-shaped electrode 815a is present, the range of about 1.300 μm to about 4.300 μm is the region where neither the comb-shaped electrode 815a nor the comb-shaped electrode 815b is present, the range of about 4.300 μm to about 6.900 μm is the region where the comb-shaped electrode 815b is present, the range of about 6.900 μm to about 9.900 μm is the region where neither the comb-shaped electrode 815b nor the comb-shaped electrode 815a is present, the range of about 9.900 μm to 11.200 μm is the region where the right-side comb-shaped electrode 815a is present, the range of 0.000 μm to about 7.600 μm is the region where the lower electrode 816 is present, region 1 is the range of 0.000 μm to about 5.600 μm, and region 3 is the range of about 5.600 μm to 11.200 μm. On the left vertical axis in FIG. 10, (I) 0.000 μm is the interface between the glass substrate 818a and the insulating layer 819a, (II) 0.000 μm is the interface between the insulating layer 819a and the liquid crystal layer 821, (III) 0.000 μm is the interface between the liquid crystal layer 821 and the insulating layer 819b, and (IV) 1.500 μm is the interface between the insulating layer 819b and the opposite electrode 820. The transmittance of the liquid crystal display device according to Working Example 2 shown in FIG. 4 is the transmittance measured in the region corresponding to the range 0.000 μm to 11.200 μm on the horizontal axis in FIG. 10.

As can be seen in FIG. 10, transmittance distribution in region 1 differs from transmittance distribution in region 3. It is therefore apparent that multi-V-T has been enabled within a pixel.

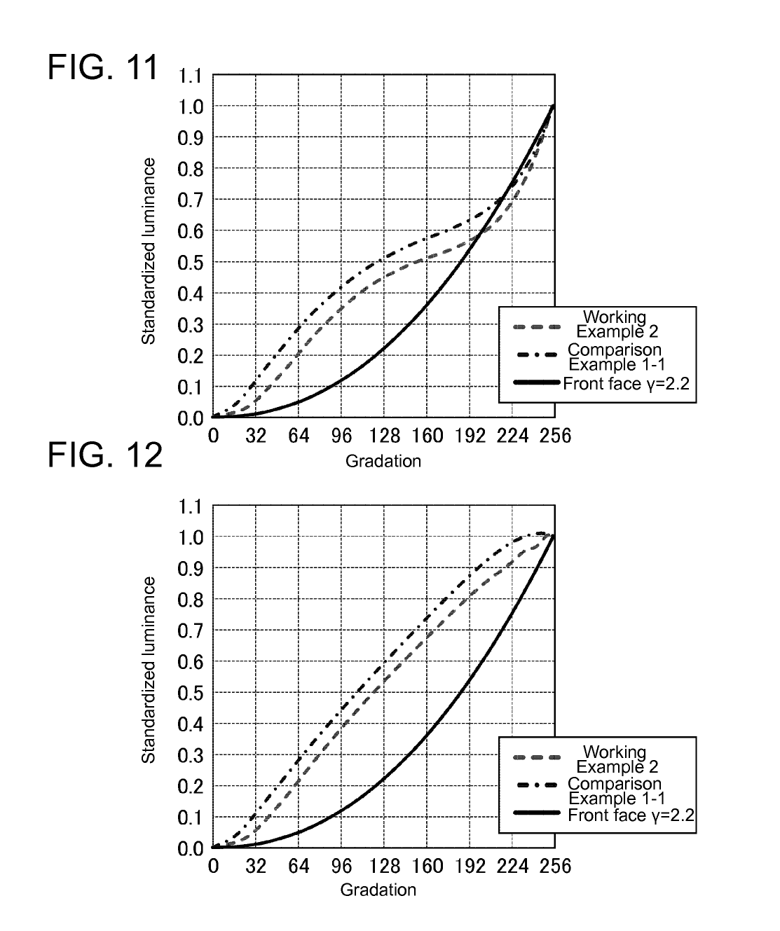

FIG. 11 shows gamma shift properties at direction angle 0°-180°, deflection angle 60° in the liquid crystal display device according to Working Example 2 and Comparison Example 1-1. FIG. 12 shows gamma shift properties at direction angle 45°-225°, deflection angle 60° in the liquid crystal display device according to Working Example 2 and Comparison Example 1-1. The horizontal axis shows gradation and the vertical axis shows the standardized luminance ratio. In FIGS. 11 and 12, ‘front face γ=2.2’ refers to the situation where observation is from the front of the liquid crystal display device, with adjustment so that γ=2.2. ‘Comparison Example 1-1’ is described below in Comparison Example 1-1. The two other curves (Working Example 2 curve and Comparison Example 1-1 curve) are curves obtained when confirming at an opposite angle 60° from the front. The direction angle is defined in the same way as shown in FIG. 1. Luminance in FIG. 11 is the mean value of luminance when confirmed at an opposite angle of 60° in the direction of angles 0° and 180°. Luminance in FIG. 12 is the mean value of luminance when confirmed at an opposite angle of 60° in the direction of angles 45° and 225°.

As can be seen in FIGS. 11 and 12, the curve for the liquid crystal display device according to Working Example 2 has shifted in a direction with a lower luminance than that of the liquid crystal display device according to Comparison Example 1-1 described below. In other words, the curve for the liquid crystal display device according to Working Example 2 has less gamma shift from the front than does the curve for the liquid crystal display device according to Comparison Example 1-1. It is therefore apparent that the viewing angle properties of the liquid crystal display device according to Working Example 2 are better than the viewing angle properties of the liquid crystal display device according to Comparison Example 1-1. Furthermore, as is the case with region 3 in the liquid crystal display device according to Working Example 2, by forming a region where part of the region between a finger of the comb-shaped electrode 815a and a finger of comb-shaped electrode 815b overlaps with the lower electrode 816, V-T properties can be easily controlled, and it is also therefore possible to combine V-T properties so that the viewing angle properties on the low gradation side are particularly improved, for example, and thus to obtain the desired viewing angle properties.

The liquid crystal molecule rising response properties in the liquid crystal display device according to Working Example 2 are described with reference to FIG. 8. As can be seen in FIG. 8, the curve for the liquid crystal display device according to Working Example 2 shows the same response properties as the curves for the liquid crystal display device according to Working Example 1 and Comparison Example 1-1 described below. In other words, it is apparent that the liquid crystal molecule rising response rate in the liquid crystal display device according to Working Example 2 is substantially equal to the liquid crystal molecule rising response rate in the liquid crystal display device according to Working Example 1 and Comparison Example 1-1 described below. This is because, by making the comb-shaped electrode spacing in the liquid crystal display device according to Working Example 2 equal to the comb-shaped electrode spacing in the liquid crystal display device according to Working Example 1 and Comparison Example 1-1, the electric field strength generated between the comb-shaped electrodes in the liquid crystal display device according to Working Example 2 becomes substantially equal to the electric field strength generated between the comb-shaped electrodes in the liquid crystal display device according to Working Example 1 and Comparison Example 1-1. Also, it is apparent that the liquid crystal molecule rising response rate in the liquid crystal display device according to Working Example 2 is faster than the liquid crystal molecule rising response rate in the liquid crystal display device according to Comparison Examples 1-2 and 1-3 described below. This is because, by making the comb-shaped electrode spacing in the liquid crystal display device according to Working Example 2 narrower than the comb-shaped electrode spacing in the liquid crystal display device according to Comparison Examples 1-2 and 1-3, the electric field strength generated between the comb-shaped electrodes in the liquid crystal display device according to Working Example 2 becomes stronger than the electric field strength generated between the comb-shaped electrodes in the liquid crystal display device according to Comparison Examples 1-2 and 1-3.

It is therefore apparent from the above description that the liquid crystal display device according to Working Example 2 is capable of enabling multi-V-T within a pixel and adequately improving viewing angle properties while adequately preventing any decrease in the liquid crystal molecule rising response rate.

### Embodiment 3

### The Area Ratio of the First Region and Second Region is 1:1 and a Circularly Polarizing Plate is Used

The configuration of the liquid crystal display device according to Embodiment 3 is that of the liquid crystal display device according to Embodiment 1, but has a pair of circularly polarizing plates (not shown) on the glass substrates 18a and 18b, on the side opposite the liquid crystal layer 21 side. Other configurations of the liquid crystal display device according to Embodiment 3 are the same as the liquid crystal display device according to Embodiment 1.

Manufactured working examples of the liquid crystal display device according to Embodiment 3 are described below.

### Working Example 3

In Working Example 3, the physical properties of the liquid crystal material, the thickness of the liquid crystal layer, the transmittance and thickness of the insulating layer, the length and spacing of the comb-shaped electrodes and the voltage (potential difference) applied to each electrode, and so forth, are the same as in Working Example 1.

Below are described the V-T properties of regions 1 and 2 in the liquid crystal display device according to Working Example 3, and gamma shift related to the V-T properties and viewing angle properties and the liquid crystal molecule rising response rate of the liquid crystal display device according to Working Example 3.

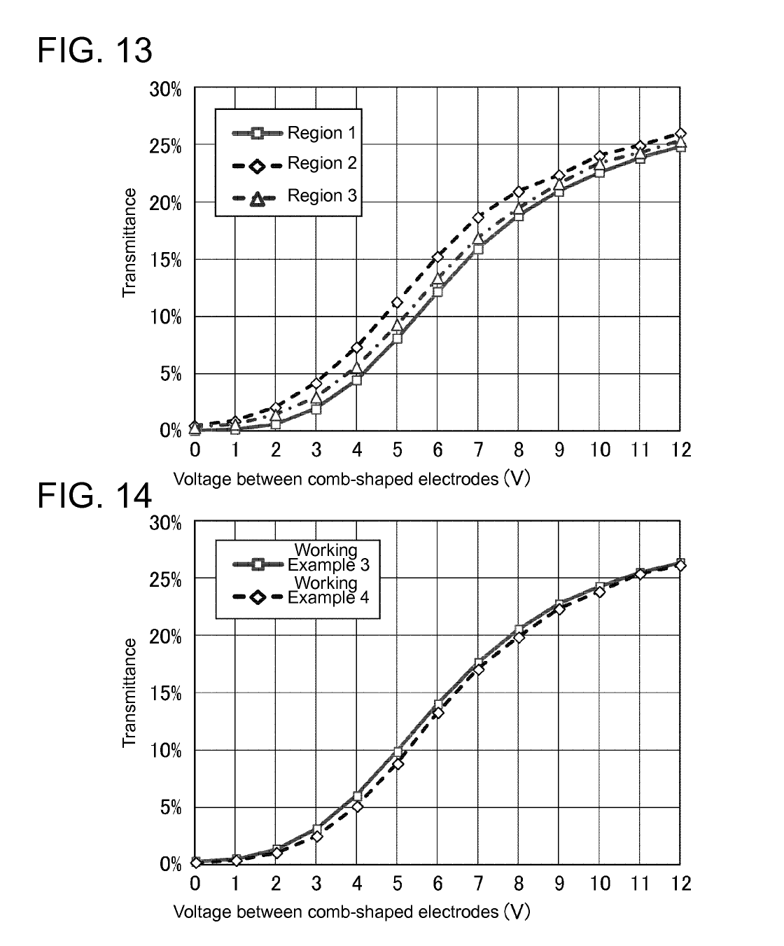

FIG. 13 is a graph showing V-T properties in each region in the liquid crystal display device according to Working Examples 3 and 4. The horizontal axis shows voltage between comb-shaped electrodes and the vertical axis shows transmittance. ‘Region 3’ in FIG. 13 is described below in Working Example 4.

As shown in FIG. 13, the V-T properties in region 1 are characterized by more of a shift to the high voltage side than the V-T properties in region 2, showing that the V-T properties in region 1 differ from the V-T properties in region 2. It is thus apparent that the liquid crystal display device of Working Example 3 has two different V-T properties, as described above, and has therefore enabled multi-V-T within the aforementioned pixel 10.

FIG. 14 is a graph showing V-T properties in a liquid crystal display device according to Working Examples 3 and 4. The horizontal axis shows voltage between comb-shaped electrodes and the vertical axis shows transmittance. ‘Working Example 4’ in FIG. 14 is described below in Working Example 4.

As shown in FIG. 14, the V-T properties of the liquid crystal display device according to Working Example 3 are a synthesis of the V-T properties in region 1 and the V-T properties in region 2.

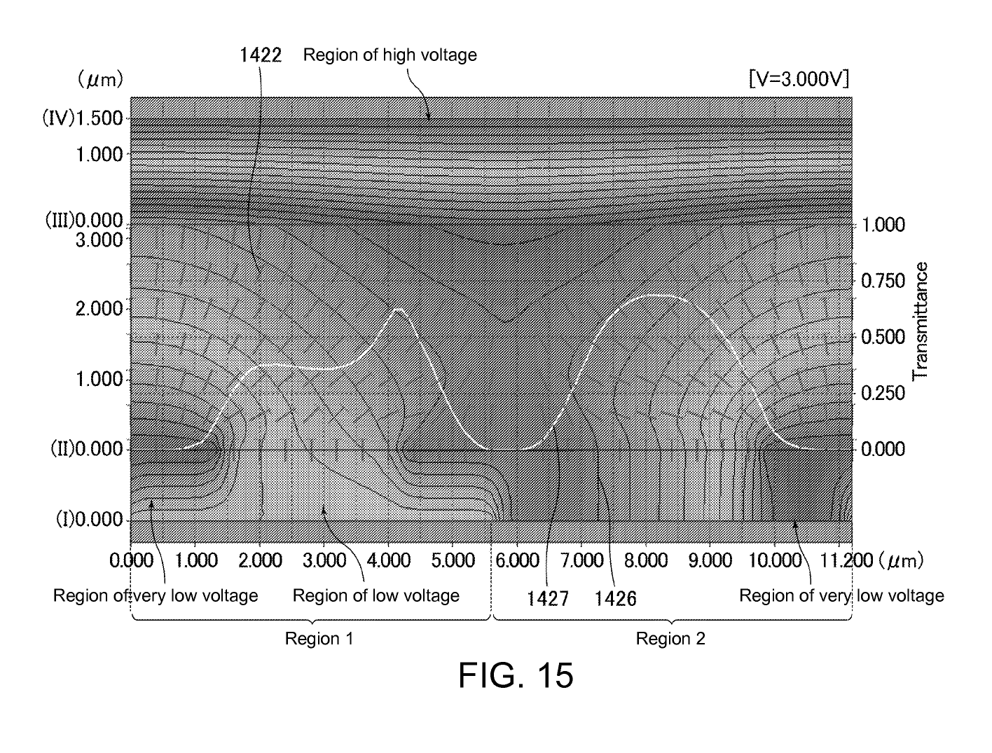

FIG. 15 shows director distribution and transmittance distribution in the liquid crystal display device according to Working Example 3. FIG. 15 shows directors 1422, electric field distribution (equipotential lines) 1426 and transmittance distribution 1427 when the voltage between the comb-shaped electrodes 15a and 15b is 6[V] (corresponding to V=3.00[V] shown in FIG. 15). The relationships between the values on the horizontal axis and the left vertical axis in FIG. 15 and the positions of the parts shown in FIG. 2 are the same as in Working Example 1. Also, the transmittance of the liquid crystal display device according to Working Example 3 shown in FIG. 14 is the transmittance measured in the region corresponding to the range 0.000 μm to 11.200 μm on the horizontal axis in FIG. 15.

As can be seen in FIG. 15, transmittance distribution in region 1 differs from transmittance distribution in region 2. It is therefore apparent that multi-V-T has been enabled within the pixel 10.

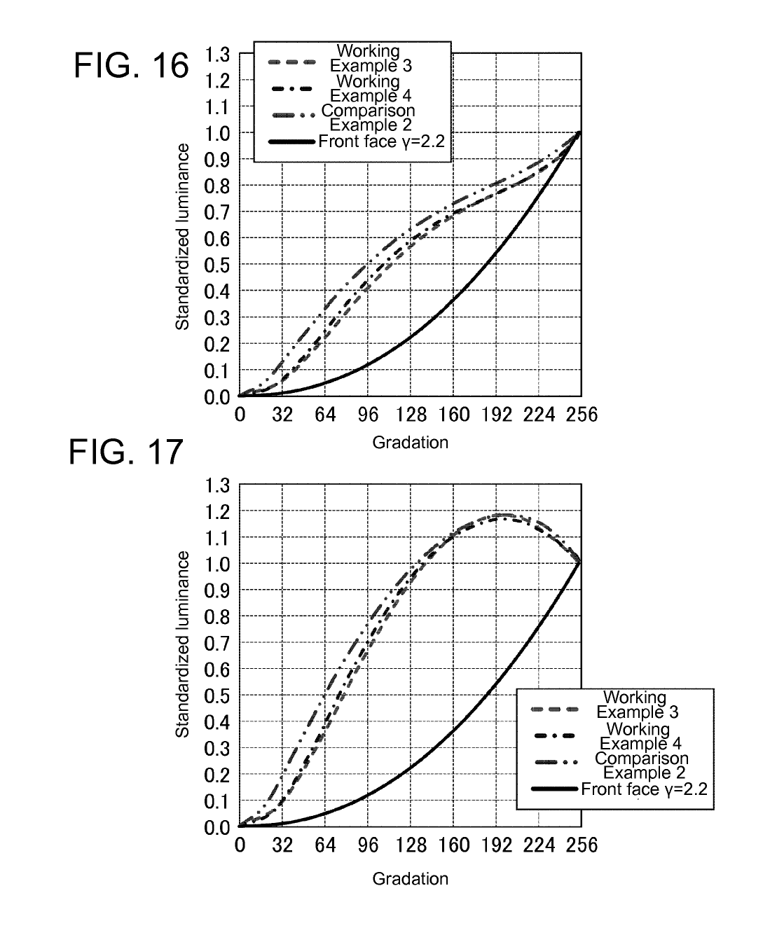

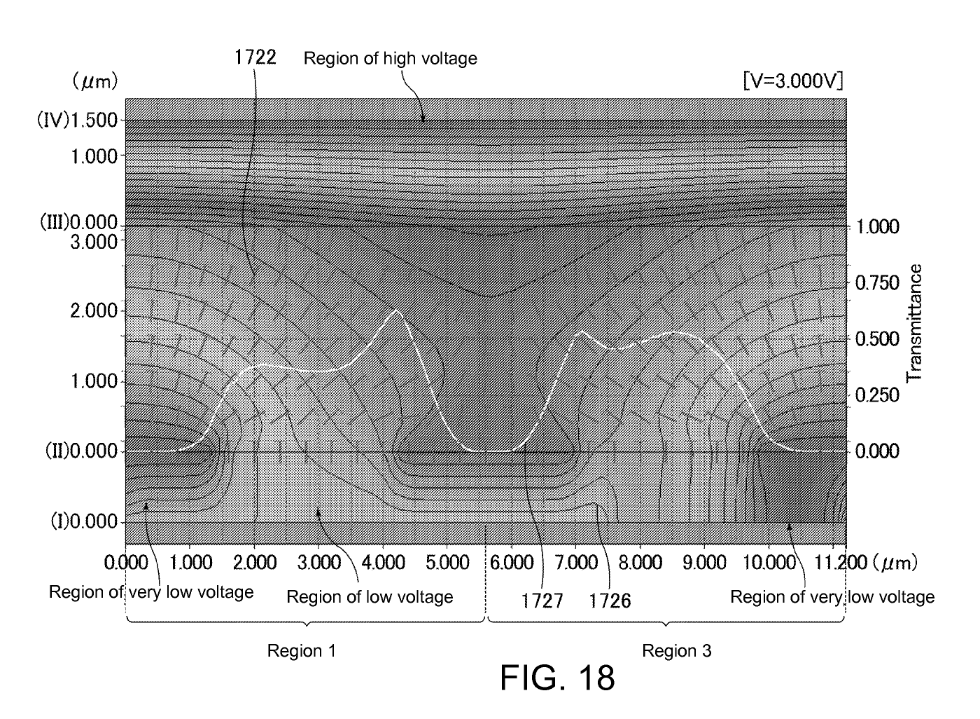

FIG. 16 shows gamma shift properties at direction angle 0°-180°, deflection angle 60° in the liquid crystal display device according to Working Examples 3 and 4 and Comparison Example 2. FIG. 17 shows gamma shift properties at direction angle 45°-225°, deflection angle 60° in the liquid crystal display device according to Working Examples 3 and 4 and Comparison Example 2. The horizontal axis shows gradation and the vertical axis shows the standardized luminance ratio. In FIGS. 16 and 17, ‘front face γ=2.2’ refers to the situation where observation is from the front of the liquid crystal display device, with adjustment so that γ=2.2. ‘Working Example 4’ and ‘Comparison Example 2’ are described below. The other three curves (Working Example 3 curve, Working Example 4 curve, Comparison Example 2 curve) are curves obtained when confirming at an opposite angle 60° from the front. The direction angle is defined in the same way as shown in FIG. 1. Luminance in FIG. 16 is the mean value of luminance when confirmed at an opposite angle of 60° in the direction of angles 0° and 180°. Luminance in FIG. 17 is the mean value of luminance when confirmed at an opposite angle of 60° in the direction of angles 45° and 225°.

As can be seen in FIGS. 16 and 17, the curve for the liquid crystal display device according to Working Example 3 has shifted in a direction with a lower luminance than that of the liquid crystal display device according to Comparison Example 2 described below. In other words, the curve for the liquid crystal display device according to Working Example 3 has less gamma shift from the front than does the curve for the liquid crystal display device according to Comparison Example 2. It is therefore apparent that the viewing angle properties of the liquid crystal display device according to Working Example 3 are better than the viewing angle properties of the liquid crystal display device according to Comparison Example 2.

It is also clear that the liquid crystal molecule rising response rate in the liquid crystal display device according to Working Example 3 will be the same as the liquid crystal molecule rising response rate in the liquid crystal display device according to Working Example 1, as long as the spacing of the comb-shaped electrodes in the liquid crystal display device according to Working Example 3 is equal to the spacing of the comb-shaped electrodes in the liquid crystal display device according to Working Example 1.

It is therefore apparent from the above description that the liquid crystal display device according to Working Example 3 is capable of enabling multi-V-T within a pixel and adequately improving viewing angle properties while adequately preventing any decrease in the liquid crystal molecule rising response rate.

### Embodiment 4

### The Area Ratio of the First Region and Third Region is 1:1 and a Circularly Polarizing Plate is Used

The structure of the liquid crystal display device according to Embodiment 4 is that of the liquid crystal display device according to Embodiment 2, but has a pair of circularly polarizing plates (not shown) on the glass substrates 818a and 818b, on the side opposite the liquid crystal layer 821 side. Other configurations of the liquid crystal display device according to Embodiment 4 are the same as the liquid crystal display device according to Embodiment 2.

Manufactured working examples of the liquid crystal display device according to Embodiment 4 are described below.

### Working Example 4

In Working Example 4, the physical properties of the liquid crystal material, the thickness of the liquid crystal layer, the transmittance and thickness of the insulating layer, the length and spacing of the comb-shaped electrodes and the voltage (potential difference) applied to each electrode, and so forth, are the same as in Working Example 2.

Below are described the V-T properties of regions 1 and 3 in the liquid crystal display device according to Working Example 4, and gamma shift related to the V-T properties and viewing angle properties and the liquid crystal molecule rising response rate of the liquid crystal display device according to Working Example 4.

The V-T properties in regions 1 and 3 in the liquid crystal display device according to Working Example 4 are described with reference to FIG. 13. As can be seen in FIG. 13, the V-T properties in region 1 are characterized by more of a shift to the high voltage side than the V-T properties in region 3, showing that the V-T properties in region 1 differ from V-T properties in region 3. It is thus apparent that the liquid crystal display device of Working Example 4 has two different V-T properties, as described above, and has therefore enabled multi-V-T within a pixel. It is also apparent that by forming region 3, it is possible to obtain V-T properties between the V-T properties in region 1 and the V-T properties in region 2.

The V-T properties in the liquid crystal display device according to Working Example 4 are described with reference to FIG. 14. As shown in FIG. 14, the V-T properties of the liquid crystal display device according to Working Example 4 are a synthesis of the V-T properties in region 1 and the V-T properties in region 3.

FIG. 18 shows director distribution and transmittance distribution in the liquid crystal display device according to Working Example 4. FIG. 18 shows directors 1722, electric field distribution (equipotential lines) 1726 and transmittance distribution 1727 when the voltage between the comb-shaped electrodes 815a and 815b is 6[V] (corresponding to V=3.00[V] shown in FIG. 18). The relationships between the values on the horizontal axis and the left vertical axis in FIG. 18 and the positions of the parts shown in FIG. 9 are the same as in Working Example 2. Also, the transmittance of the liquid crystal display device according to Working Example 4 shown in FIG. 14 is the transmittance measured in the region corresponding to the range 0.000 μm to 11.200 μm on the horizontal axis in FIG. 18.

As can be seen in FIG. 18, transmittance distribution in region 1 differs from transmittance distribution in region 3. It is therefore apparent that multi-V-T has been enabled within a pixel.

Gamma shift related to the viewing angle properties in the liquid crystal display device according to Working Example 4 is described with reference to FIGS. 16 and 17. As can be seen in FIGS. 16 and 17, the curve for the liquid crystal display device according to Working Example 4 has shifted in a direction with a lower luminance than that of the liquid crystal display device according to Comparison Example 2 described below. In other words, the curve for the liquid crystal display device according to Working Example 4 has less gamma shift from the front than does the curve for the liquid crystal display device according to Comparison Example 2. It is therefore apparent that the viewing angle properties of the liquid crystal display device according to Working Example 4 are better than the viewing angle properties of the liquid crystal display device according to Comparison Example 2. Furthermore, as is the case with region 3 in the liquid crystal display device according to Working Example 4, by forming a region where part of the region between a finger of the comb-shaped electrode 815a and a finger of comb-shaped electrode 815b overlaps with the lower electrode 816, V-T properties can be easily controlled, and it is also therefore possible to combine V-T properties so that the viewing angle properties on the low gradation side are particularly improved, for example, and thus to obtain the desired viewing angle properties.

It is also clear that the liquid crystal molecule rising response rate in the liquid crystal display device according to Working Example 4 is the same as the liquid crystal molecule rising response rate in the liquid crystal display device according to Working Example 2, as long as the spacing of the comb-shaped electrodes in the liquid crystal display device according to Working Example 4 is equal to the spacing of the comb-shaped electrodes in the liquid crystal display device according to Working Example 2.

It is therefore apparent from the above description that the liquid crystal display device according to Working Example 4 is capable of achieving multi-V-T within a pixel and adequately improving viewing angle properties while adequately preventing any decrease in the liquid crystal molecule rising response rate.

### Embodiment 5

### The Area Ratio of the First Region and Second Region is 1:1 and the Configuration is Different from that of Embodiment 1

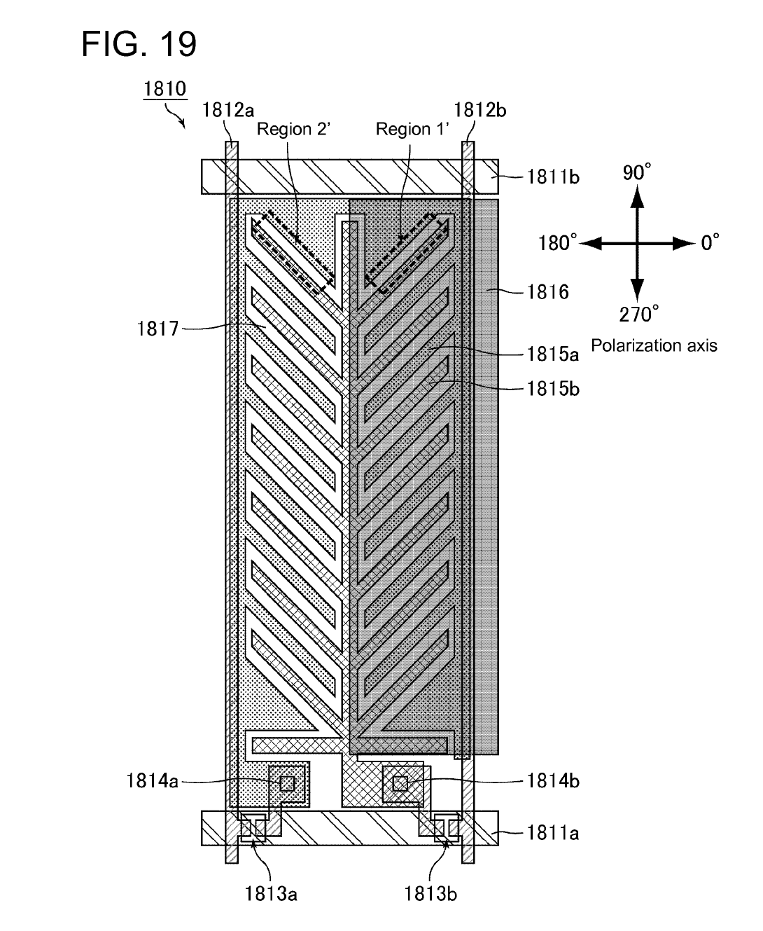

The liquid crystal display device according to Embodiment 5 is described with reference to FIG. 19.

FIG. 19 is a schematic plan view of a pixel of a liquid crystal display panel provided in a liquid crystal display device according to Embodiment 5. In the liquid crystal display device according to Embodiment 5, within a pixel 1810 and at a timing chosen by a gate bus line 1811a, a voltage supplied from a source bus line 1812a is applied through a TFT 1813a and a contact hole 1814a to a comb-shaped electrode 1815a, which is one of a pair of comb-shaped electrodes that drive a liquid crystal layer, and a voltage supplied from a source bus line 1812b is applied through a TFT 1813b and a contact hole 1814b to a comb-shaped electrode 1815b, which is the other of the pair of comb-shaped electrodes. Also, a plurality of mutually parallel slits 1817 is formed in the lower electrode 1816. The slits 1817 correspond to the openings in the third electrode in one aspect of the present invention.

Here, as illustrated in part of FIG. 19, Embodiment 5 is an embodiment in which, when region 1′ is defined as the region of overlap between the lower electrode 1816 and the whole of the region between a finger of the comb-shaped electrode 1815a and a finger of the comb-shaped electrode 1815b, which are a mutually adjacent pair, and region 2′ is defined as the region of non-overlap between the lower electrode 1816 and a region between a finger of the comb-shaped electrode 1815a and a finger of the comb-shaped electrode 1815b, which are a mutually adjacent pair, region 1′ and region 2′ are arranged so as to divide the pixel 1810 into two parts, and the area ratio of region 1′ and region 2′ is 1:1. The comb-shaped electrodes 1815a and 1815b correspond respectively to the first and second electrodes of one aspect of the present invention. The lower electrode 1816 corresponds to the third electrode of one aspect of the present invention. In addition, region 1′ and region 2′ correspond respectively to the aforementioned first region and second region in one aspect of the present invention. The liquid crystal display device according to Embodiment 5 also possesses a pair of linear polarizing plates (not shown) or a pair of circularly polarizing plates (not shown).

Here, it is clear that as long as the area ratio between the first region and the second region is 1:1, as described above, the same effect as in the liquid crystal display device according to Embodiment 1 will be obtained in the liquid crystal display device according to Embodiment 5.

### Embodiment 6

### The Area Ratio of the First Region and the Second Region is 1:3

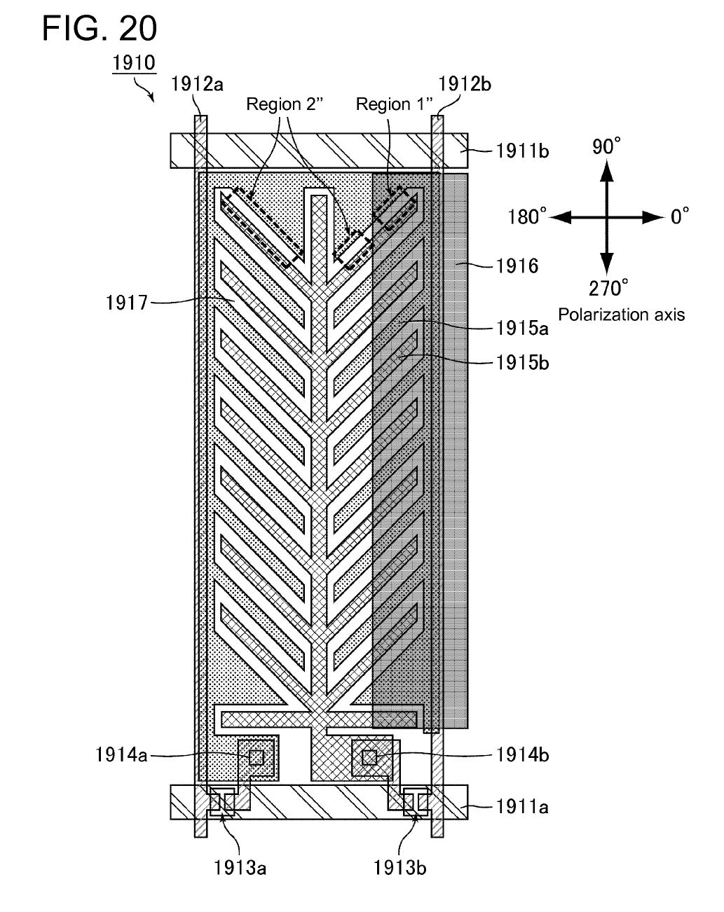

The liquid crystal display device according to Embodiment 6 is described with reference to FIG. 20.

FIG. 20 is a schematic plan view of a pixel of a liquid crystal display panel provided in a liquid crystal display device according to Embodiment 6. In the liquid crystal display device according to Embodiment 6, within a pixel 1910 and at a timing chosen by a gate bus line 1911a, a voltage supplied from a source bus line 1912a is applied through a TFT 1913a and a contact hole 1914a to a comb-shaped electrode 1915a, which is one of a pair of comb-shaped electrodes that drive a liquid crystal layer, and a voltage supplied from a source bus line 1912b is applied through a TFT 1913b and a contact hole 1914b to a comb-shaped electrode 1915b, which is the other of the pair of comb-shaped electrodes. Also, a plurality of mutually parallel slits 1917 is formed in a lower electrode 1916. The slits 1917 correspond to the openings in the third electrode in one aspect of the present invention.

Here, as illustrated in part of FIG. 20, Embodiment 6 is an embodiment in which, when region 1″ is defined as the region of overlap between the lower electrode 1916 and the whole of the region between a finger of the comb-shaped electrode 1915a and a finger of the comb-shaped electrode 1915b, which are a mutually adjacent pair, and region 2″ is defined as the region of non-overlap between the lower electrode 1916 and a region between a finger of the comb-shaped electrode 1915a and a finger of the comb-shaped electrode 1915b, which are a mutually adjacent pair, the area ratio of region 1″ and region 2″ is 1:3. The comb-shaped electrodes 1915a and 1915b correspond respectively to the first and second electrodes of one aspect of the present invention. The lower electrode 1916 corresponds to the third electrode of one aspect of the present invention. In addition, region 1″ and region 2″ correspond respectively to the aforementioned first and second regions in one aspect of the present invention. The liquid crystal display device according to Embodiment 6 also possesses a pair of linear polarizing plates (not shown) or a pair of circularly polarizing plates (not shown).

Here, it is clear that as long as there are a first region and a second region with different electrode structures within a pixel, the same effect as in the liquid crystal display device according to Embodiment 1 will be obtained.

### Embodiment 7

### The Width of an Opening of the Third Electrode in a Region Between a Finger of the First Electrode and an Adjacent Finger of the Second Electrode Varies Along the Length of the First and the Second Electrodes

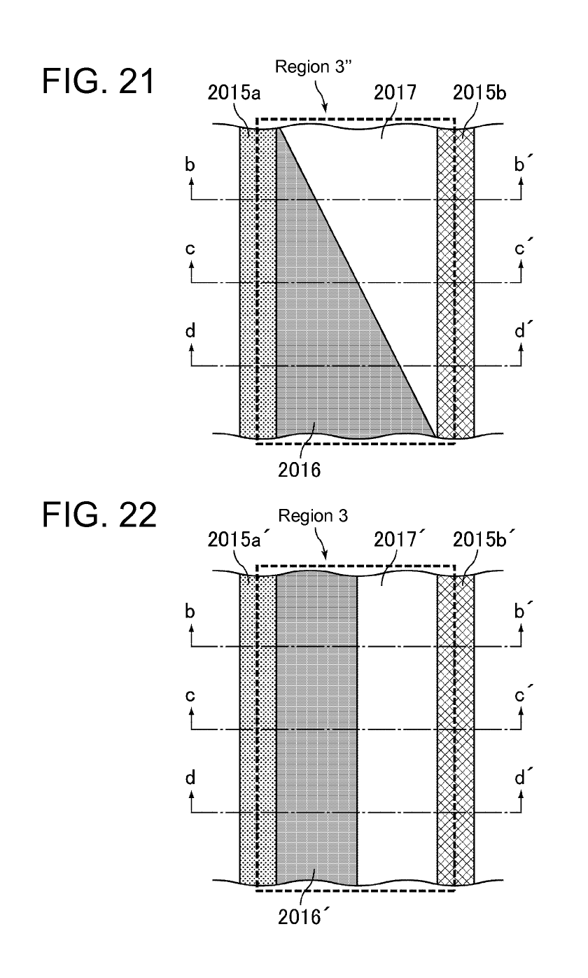

The liquid crystal display device according to Embodiment 7 is described with reference to FIG. 21.

FIG. 21 is a schematic plan view showing the space between an adjacent pair of comb-shaped electrodes in a pixel of a liquid crystal display panel provided in a liquid crystal display device according to Embodiment 7. As shown in FIG. 21, Embodiment 7 is an embodiment in which, when region 3″ is defined as the region of overlap between a lower electrode 2016 and part of a region between a finger of a comb-shaped electrode 2015a and a finger of a comb-shaped electrode 2015b, which are a mutually adjacent pair, the width of a slit 2017 in the lower electrode 2016 varies along the length of the comb-shaped electrodes 2015a and 2015b. For example, Embodiment 7 is an embodiment in which the width of the slit 2017 in the lower electrode 2016 differs in line b-b′, line c-c′ and line d-d′, as shown in FIG. 21. The comb-shaped electrodes 2015a and 2015b correspond respectively to the first and second electrodes of one aspect of the present invention. The lower electrode 2016 corresponds to the third electrode of one aspect of the present invention. Region 3″ corresponds to the third region of one aspect of the present invention. Also, the slits 2017 correspond to the openings in the third electrode in one aspect of the present invention. Furthermore, the liquid crystal display device according to Embodiment 7 also possesses a pair of linear polarizing plates (not shown) or a pair of circularly polarizing plates (not shown).

Here, the same effects as those in the above-described liquid crystal display device according to Embodiment 2 will be obtained in the liquid crystal display device according to Embodiment 7 in the configuration shown in FIG. 22, for example. FIG. 22 is a schematic plan view showing the space between an adjacent pair of comb-shaped electrodes in a pixel when slits in the lower electrode are of a fixed width. As shown in FIG. 22, when there is a region between a finger of a comb-shaped electrode 2015a′ and a finger of a comb-shaped electrode 2015b′, which are a mutually adjacent pair, and the region of overlap between part of this region and a lower electrode 2016′ is defined as region 3, then the aspect shown in FIG. 22 is an aspect in which the length of a slit 2017′ in the lower electrode 2016′ is constant along the length of the comb-shaped electrodes 2015a′ and 2015b′ in region 3. For example, the aspect shown in FIG. 22 is an aspect in which the width of the slit 2017′ in the lower electrode 2016′ is the same in line b-b′, line c-c′ and line d-d′. The comb-shaped electrodes 2015a′ and 2015b′ correspond respectively to the first and second electrodes of one aspect of the present invention. The lower electrode 2016′ corresponds to the third electrode of one aspect of the present invention. Region 3 corresponds to the third region in one aspect of the present invention. Also, the slits 2017′ correspond to the openings in the third electrode in one aspect of the present invention.

<Comparison Aspect 1: The Lower Electrode does not have an Opening, and Linear Polarizing Plates are Used>

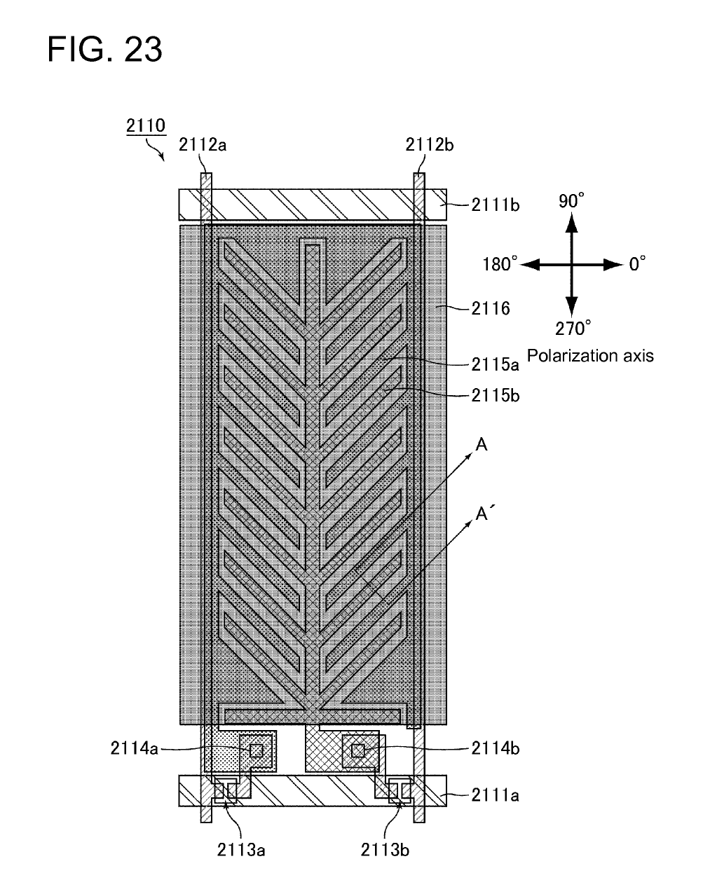

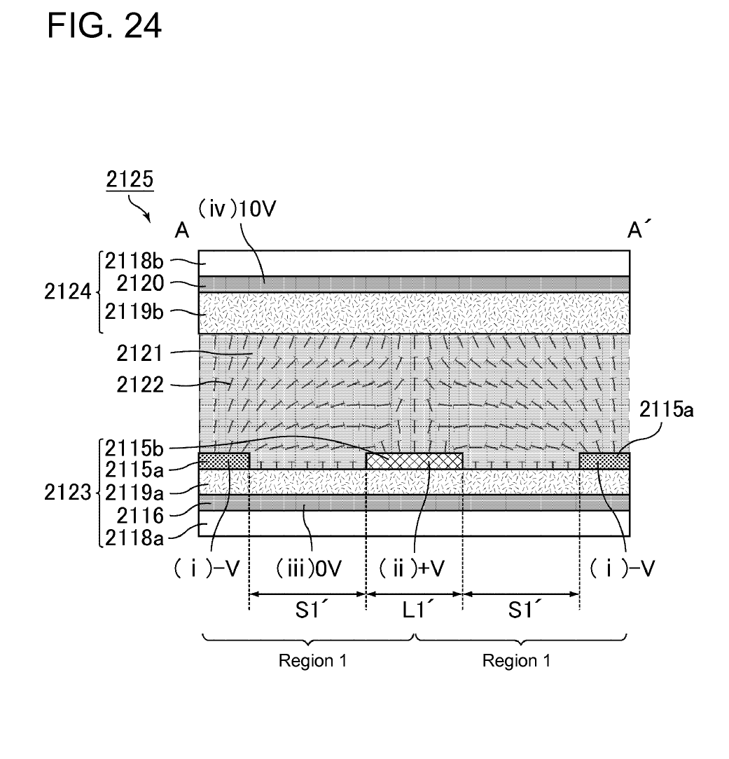

The liquid crystal display device according to Comparison Aspect 1 is described with reference to FIGS. 23 and 24.

FIG. 23 is a schematic plan view of a pixel of a liquid crystal display panel provided in a liquid crystal display device according to Comparison Aspect 1. In the liquid crystal display device according to Comparison Aspect 1, within a pixel 2110 and at a timing chosen by a gate bus line 2111a, a voltage supplied from a source bus line 2112a is applied through a TFT 2113a and a contact hole 2114a to a comb-shaped electrode 2115a, which is one of a pair of comb-shaped electrodes that drive a liquid crystal layer, and a voltage supplied from a source bus line 2112b is applied through a TFT 2113b and a contact hole 2114b to a comb-shaped electrode 2115b, which is the other of the pair of comb-shaped electrodes. The lower electrode 2116 is planar and does not have an opening.

FIG. 24 is a schematic cross-sectional view showing the section corresponding to the line A-A′ in FIG. 23. A basic structure of a liquid crystal display panel 2125 provided in the liquid crystal display device of Comparison Aspect 1 includes a lower substrate 2123, an upper substrate 2124, and a liquid crystal layer 2121 enclosed between the two substrates. The liquid crystal molecules 2122 contained in the liquid crystal layer 2121 have positive dielectric anisotropy (Δ∈>0).

In the liquid crystal display device according to Comparison Aspect 1, the lower substrate 2123 has a glass substrate 2118a, a lower electrode 2116 formed on the glass substrate 2118a, on the liquid crystal layer 2121 side of the glass substrate 2118a, an insulating layer 2119a formed on the lower electrode 2116, on the liquid crystal layer 2121 side of the lower electrode 2116, and a pair of comb-shaped electrodes 2115a and 2115b, formed on the insulating layer 2119a, on the liquid crystal layer 2121 side of the insulating layer 2119a. Also, the comb-shaped electrodes 2115a and 2115b are formed on the same layer. As shown in FIG. 24, Comparison Aspect 1 is an embodiment in which, when region 1 is defined as the region of overlap between the lower electrode 2116 and the whole of a region between a finger of the comb-shaped electrode 2115a and a finger of the comb-shaped electrode 2115b, which are a mutually adjacent pair, region 1 is arranged consecutively.

In the liquid crystal display device according to Comparison Aspect 1, the upper substrate 2124 has a glass substrate 2118b, a planar opposite electrode 2120 formed on the glass substrate 2118b, on the liquid crystal layer 2121 side of the glass substrate 2118b, and an insulating layer 2119b formed on the opposite electrode 2120, on the liquid crystal layer 2121 side of the opposite electrode 2120. The insulating layer 2119b may be omitted.

The liquid crystal display panel 2125 provided in the liquid crystal display device according to Comparison Aspect 1 further has a pair of linear polarizing plates (not shown) on the glass substrates 2118a and 2118b, on the side opposite the liquid crystal layer 2118 side.

In the liquid crystal display device according to Comparison Aspect 1, constant generation of an electric field is maintained in the liquid crystal layer 2121 by generation of a fixed potential difference between the lower electrode 2116 and the opposite electrode 2120. A potential difference is then generated by applying a reversed polarity voltage between the comb-shaped electrodes 2115a and 2115b, and the strength of the horizontal electric field is controlled by varying the potential difference between the comb-shaped electrodes 2115a and 2115b, thus achieving a gradation display.

In FIG. 24, (i), (ii), (iii) and (iv) are, respectively, the potential of the comb-shaped electrode 2115a, the potential of the comb-shaped electrode 2115b, the potential of the lower electrode 2116 and the potential of the opposite electrode 2120.

Manufactured Comparison Examples of the liquid crystal display device according to Comparison Aspect 1 are described below.

### Comparison Example 1-1

### The Comb-Shaped Electrode Spacing is 3 μm

In Comparison Example 1-1, the liquid crystal molecules 2122 have positive dielectric anisotropy, the dielectric anisotropy Δ∈ is 18 and the refractive-index anisotropy Δn is 0.12. The thickness of the liquid crystal layer 2121 is 3.2 μm. The insulating layer 2119a has a transmittance of 7 and a thickness of 0.3 μm. The insulating layer 2119b has a transmittance of 4 and a thickness of 1.5 μm. The electrode width L1′ of the comb-shaped electrode 2115b is 1.5 μm and the electrode spacing S1′ between the comb-shaped electrodes 2115a and 2115b is 3 μm. The electrode width (not shown) of the comb-shaped electrode 2115a is equal to the electrode width L1′ of the comb-shaped electrode 2115b.

As shown in FIG. 24, in Comparison Example 1-1 the comb-shaped electrode 2115a has a potential (i) of −V[V], the comb-shaped electrode 2115b has a potential (ii) of +V[V], the lower electrode 2116 has a potential (iii) of 0[V] and the opposite electrode 2120 has a potential (iv) of 10[V] (above, [V] is the unit). Also, the lower substrate 2123 is a TFT substrate and the upper substrate 2124 is a CF substrate.

Gamma shift related to the V-T properties and viewing angle properties and the liquid crystal molecule rising response properties of the liquid crystal display device according to Comparison Example 1-1 were measured using the above-described conditions. The results are described below.

The V-T properties in the liquid crystal display device according to Comparison Example 1-1 are described with reference to FIG. 3. It can be seen from FIG. 3 that because the V-T properties in the liquid crystal display device according to Comparison Example 1-1 are equal to the V-T properties in region 1 between all comb-shaped electrodes within a pixel, it is not possible to enable multi-V-T within the pixel 2010.

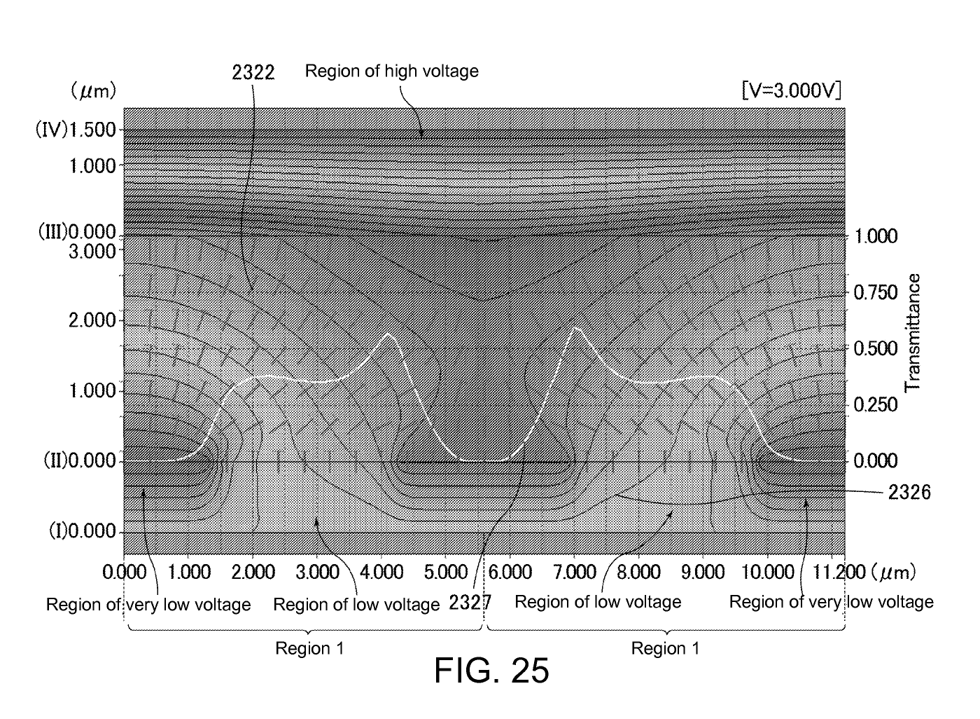

FIG. 25 shows director distribution and transmittance distribution in a liquid crystal display device according to Comparison Example 1-1. FIG. 25 shows directors 2322, electric field distribution (equipotential lines) 2326 and transmittance distribution 2327 when the voltage between the comb-shaped electrodes 2115a and 2115b is 6[V] (corresponding to V=3.00[V] shown in FIG. 25).

The relationship between the values on the horizontal axis and left vertical axis in FIG. 25 and the positions of the parts shown in FIG. 24 are described below. In the horizontal axis in FIG. 25, the range of 0.000 μm to about 1.300 μm is the region where the left-side comb-shaped electrode 2115a is present, the range of about 1.300 μm to about 4.300 μm is the region where neither the comb-shaped electrode 2115a nor the comb-shaped electrode 2115b is present, the range of about 4.300 μm to about 6.900 μm is the region where the comb-shaped electrode 2115b is present, the range of about 6.900 μm to about 9.900 μm is the region where neither the comb-shaped electrode 2115b nor the comb-shaped electrode 2115a is present, the range of about 9.900 μm to 11.200 μm is the region where the right-side comb-shaped electrode 2115a is present, the range of 0.000 μm to 11.200 μm is the region where the lower electrode 2116 is present, and region 1 is the range of 0.000 μm to 11.200 μm. On the left vertical axis in FIG. 25, (I) 0.000 μm is the interface between the glass substrate 2118a and the insulating layer 2119a, (II) 0.000 μm is the interface between the insulating layer 2119a and the liquid crystal layer 2121, (III) 0.000 μm is the interface between the liquid crystal layer 2121 and the insulating layer 2119b, and (IV) 1.500 μm is the interface between the insulating layer 2119b and the opposite electrode 2120.

As can be seen in FIG. 25, transmittance distribution in region 1 on the left side has the same shape as transmittance distribution in region 1 on the right side. It is therefore apparent that multi-V-T cannot be enabled within the pixel 2110.

Gamma shift related to the viewing angle properties in the liquid crystal display device according to Comparison Example 1-1 is described with reference to FIGS. 6, 7, 11 and 12. As can be seen in FIGS. 6 and 7, the curve for the liquid crystal display device according to Comparison Example 1-1 has shifted in a direction with higher luminance than that of the liquid crystal display device according to Working Example 1. In other words, the curve for the liquid crystal display device according to Comparison Example 1-1 has greater gamma shift from the front than does the curve for the liquid crystal display device according to Working Example 1. It is therefore apparent that the viewing angle properties of the liquid crystal display device according to Comparison Example 1-1 are inferior to the viewing angle properties of the liquid crystal display device according to Working Example 1. As can be seen in FIGS. 11 and 12, the curve for the liquid crystal display device according to Comparison Example 1-1 has shifted in a direction with higher luminance than that of the liquid crystal display device according to Working Example 2. In other words, the curve for the liquid crystal display device according to Comparison Example 1-1 has greater gamma shift from the front than does the curve for the liquid crystal display device according to Working Example 2. It is therefore apparent that the viewing angle properties of the liquid crystal display device according to Comparison Example 1-1 are inferior to the viewing angle properties of the liquid crystal display device according to Working Example 2.

The liquid crystal molecule rising response properties in the liquid crystal display device according to Comparison Example 1-1 are described with reference to FIG. 8. As can be seen in FIG. 8, the curve for the liquid crystal display device according to Comparison Example 1-1 shows the same response properties as the curves for the liquid crystal display device according to Working Examples 1 and 2. In other words, it is apparent that the liquid crystal molecule rising response rate in the liquid crystal display device according to Comparison Example 1-1 is substantially equal to the liquid crystal molecule rising response rate in the liquid crystal display device according to Working Examples 1 and 2. This is because, by making the comb-shaped electrode spacing in the liquid crystal display device according to Comparison Example 1-1 equal to the comb-shaped electrode spacing in the liquid crystal display device according to Working Examples 1 and 2, the electric field strength generated between the comb-shaped electrodes in the liquid crystal display device according to Comparison Example 1-1 becomes substantially equal to the electric field strength generated between the comb-shaped electrodes in the liquid crystal display device according to Working Examples 1 and 2.

It is therefore apparent from the above description that the liquid crystal display device according to Comparison Example 1-1 adequately prevents any decrease in the liquid crystal molecule rising response rate but cannot enable multi-V-T within a pixel.

### Comparison Example 1-2

### The Comb-Shaped Electrode Spacing is 5 μm

In Comparison Example 1-2, the electrode spacing S1′ between the comb-shaped electrodes 2115a and 2115b is 5 μm. In Comparison Example 1-2, the physical properties of the liquid crystal material, the thickness of the liquid crystal layer, the transmittance and thickness of the insulating layer, the length and spacing of the comb-shaped electrodes and the voltage (potential difference) applied to each electrode, and so forth, are the same as in Comparison Example 1-1.

Gamma shift related to the V-T properties and viewing angle properties and the liquid crystal molecule rising response properties of the liquid crystal display device according to Comparison Example 1-2 are described below.

Because the spacing of comb-shaped electrodes in the liquid crystal display device according to Comparison Example 1-2 is different from the spacing of comb-shaped electrodes in the liquid crystal display device according to Comparison Example 1-1, the V-T properties in the liquid crystal display device according to Comparison Example 1-2 are different from the V-T properties in the liquid crystal display device according to Comparison Example 1-1. In the liquid crystal display device according to Comparison Example 1-2, it is possible to enable multi-V-T within a pixel, and to improve gamma shift related to viewing angle properties, by providing areas with different comb-shaped electrode spacings within an individual pixel, for example.

The liquid crystal molecule rising response properties in the liquid crystal display device according to Comparison Example 1-2 are described with reference to FIG. 8. As can be seen in FIG. 8, the liquid crystal molecule rising response rate in the liquid crystal display device according to Comparison Example 1-2 is slower than the liquid crystal molecule rising response rate in the liquid crystal display device according to Working Examples 1 and 2 and Comparison Example 1-1. This is because, by making the spacing of comb-shaped electrodes in the liquid crystal display device according to Comparison Example 1-2 wider than the spacing of comb-shaped electrodes in the liquid crystal display device according to Working Examples 1 and 2 and Comparison Example 1-1, the electric field strength generated between the comb-shaped electrodes in the liquid crystal display device according to Comparison Example 1-2 becomes weaker than the electric field strength generated between the comb-shaped electrodes in the liquid crystal display device according to Working Examples 1 and 2 and Comparison Example 1-1.

It is therefore apparent from the above description that the liquid crystal display device according to Comparison Example 1-2 can enable multi-V-T within a pixel but cannot adequately prevent any decrease in the liquid crystal molecule rising response rate.

### Comparison Example 1-3

### The Comb-Shaped Electrode Spacing is 7 μm

In Comparison Example 1-3, the electrode spacing S1′ between the comb-shaped electrodes 2115a and 2115b is 7 μm. In Comparison Example 1-3, the physical properties of the liquid crystal material, the thickness of the liquid crystal layer, the transmittance and thickness of the insulating layer, the length and spacing of the comb-shaped electrodes, the voltage (potential difference) applied to each electrode, and so forth, are the same as in Comparison Example 1-1.

Gamma shift related to the V-T properties and viewing angle properties and the liquid crystal molecule rising response properties of the liquid crystal display device according to Comparison Example 1-3 are described below.

Because the spacing of comb-shaped electrodes in the liquid crystal display device according to Comparison Example 1-3 is different from the spacing of comb-shaped electrodes in the liquid crystal display device according to Comparison Example 1-1, the V-T properties in the liquid crystal display device according to Comparison Example 1-3 are different from the V-T properties in the liquid crystal display device according to Comparison Example 1-1. In the liquid crystal display device according to Comparison Example 1-3, it is possible to enable multi-V-T within a pixel, and to improve gamma shift related to viewing angle properties, by providing areas with different comb-shaped electrode spacings within an individual pixel, for example.

The liquid crystal molecule rising response properties in the liquid crystal display device according to Comparison Example 1-3 are described with reference to FIG. 8. As can be seen in FIG. 8, the liquid crystal molecule rising response rate in the liquid crystal display device according to Comparison Example 1-3 is slower than the liquid crystal molecule rising response rate in the liquid crystal display device according to Working Examples 1 and 2 and Comparison Example 1-1. This is because, by making the spacing of comb-shaped electrodes in the liquid crystal display device according to Comparison Example 1-3 wider than the spacing of comb-shaped electrodes in the liquid crystal display device according to Working Examples 1 and 2 and Comparison Example 1-1, the electric field strength generated between the comb-shaped electrodes in the liquid crystal display device according to Comparison Example 1-3 becomes weaker than the electric field strength generated between the comb-shaped electrodes in the liquid crystal display device according to Working Examples 1 and 2 and Comparison Example 1-1.

It is therefore apparent from the above description that the liquid crystal display device according to Comparison Example 1-3 can enable multi-V-T within a pixel but cannot adequately prevent any decrease in the liquid crystal molecule rising response rate.

<Comparison Aspect 2: The Lower Electrode does not have an Opening, and a Circularly Polarizing Plate is Used>

The structure of the liquid crystal display device according to Comparison Aspect 2 is that of the liquid crystal display device according to Comparison Aspect 1, but has a pair of circularly polarizing plates (not shown) on the glass substrates 2118a and 2118b, on the side opposite the liquid crystal layer 2121 side. Other configurations of the liquid crystal display device according to Comparison Aspect 2 are the same as the liquid crystal display device according to Comparison Aspect 1.

Manufactured Comparison Examples of the liquid crystal display device according to Comparison Aspect 2 are described below.

### Comparison Example 2

In Comparison Example 2, the physical properties of the liquid crystal material, the thickness of the liquid crystal layer, the transmittance and thickness of the insulating layer, the length and spacing of the comb-shaped electrodes and the voltage (potential difference) applied to each electrode, and so forth, are the same as in Comparison Example 1-1.

Gamma shift related to the V-T properties and viewing angle properties and the liquid crystal molecule rising response properties of the liquid crystal display device according to Comparison Example 2 are described below.

Because the configuration of the liquid crystal display device according to Comparison Example 2 is the same as the configuration of the liquid crystal display device according to Comparison Example 1-1, the V-T properties of the liquid crystal display device according to Comparison Example 2 are the same as the V-T properties of the liquid crystal display device according to Comparison Example 1-1, and it is clearly not possible to enable multi-V-T within a pixel.

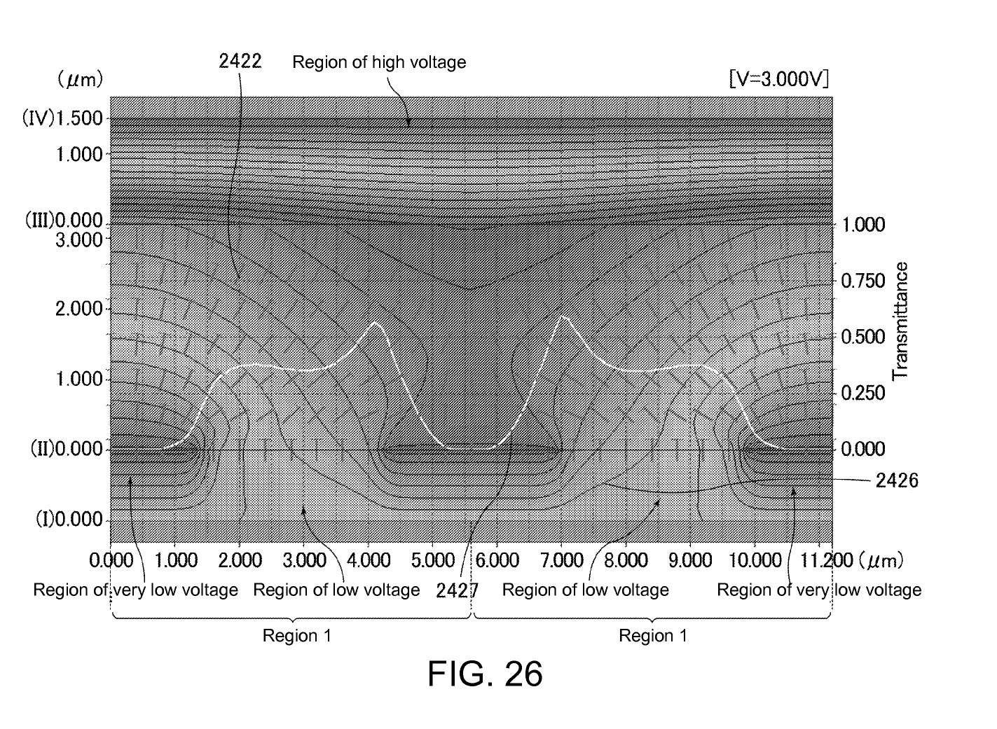

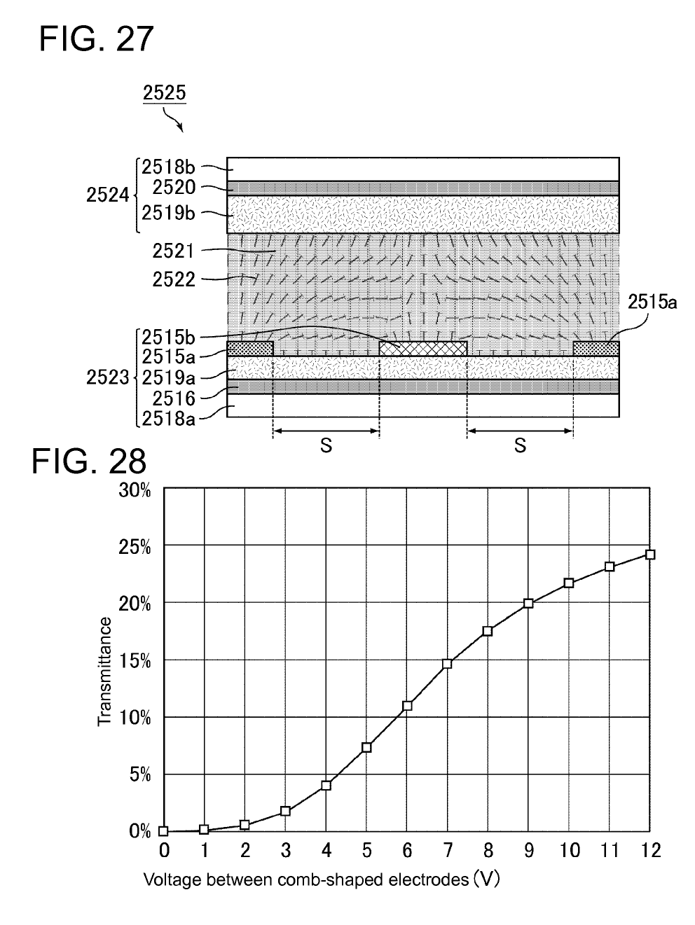

FIG. 26 shows director distribution and transmittance distribution in the liquid crystal display device according to Comparison Example 2. FIG. 26 shows directors 2422, electric field distribution (equipotential lines) 2426 and transmittance distribution 2427 when the voltage between the comb-shaped electrodes 2115a and 2115b is 6[V] (corresponding to V=3.00[V] shown in FIG. 26). The relationships between the values on the horizontal axis and the left vertical axis in FIG. 24 and the positions of the parts shown in FIG. 26 are the same as in Comparison Example 1-1.

As can be seen in FIG. 26, transmittance distribution in region 1 on the left side has the same shape as transmittance distribution in region 1 on the right side. It is therefore apparent that multi-V-T cannot be enabled within the pixel 2110.

Gamma shift related to the viewing angle properties in the liquid crystal display device according to Comparison Example 2 is described with reference to FIGS. 16 and 17. As can be seen in FIGS. 16 and 17, the curve for the liquid crystal display device according to Comparison Example 2 has shifted in a direction with higher luminance than that of the liquid crystal display device according to Working Examples 3 and 4. In other words, the curve for the liquid crystal display device according to Comparison Example 2 has greater gamma shift from the front than does the curve for the liquid crystal display device according to Working Examples 3 and 4. It is therefore apparent that the viewing angle properties of the liquid crystal display device according to Comparison Example 2 are inferior to the viewing angle properties of the liquid crystal display device according to Working Examples 3 and 4.

It is also clear that the liquid crystal molecule rising response rate in the liquid crystal display device according to Comparison Example 2 is the same as the liquid crystal molecule rising response rate in the liquid crystal display device according to Comparison Example 1-1, as long as the spacing of the comb-shaped electrodes in the liquid crystal display device according to Comparison Example 2 is equal to the spacing of the comb-shaped electrodes in the liquid crystal display device according to Comparison Example 1-1.

It is therefore apparent from the above description that the liquid crystal display device according to Comparison Example 2 adequately prevents any decrease in the liquid crystal molecule rising response rate but cannot enable multi-V-T within a pixel.

The various aspects of the embodiments described above may be appropriately combined insofar as the spirit of the present invention is not departed from.

### DESCRIPTION OF REFERENCE CHARACTERS

| | |
|---|---|
| 10, 1810, 1910, 2110 | pixel |
| 11a, 11b, 1811a, 1811b, 1911a, 1911b, | gate bus line |
| 2111a, 2111b | |
| 12a, 12b, 1812a, 1812b, 1912a, 1912b, | source bus line |
| 2112a, 2112b | |
| 13a, 13b, 1813a, 1813b, 1913a, 1913b, | TFT |
| 2113a, 2113b | |
| 14a, 14b, 1814a, 1814b, 1914a, 1914b, | contact hole |
| 2114a, 2114b | |
| 15a, 15b, 815a, 815b, 1815a, 1815b, | comb-shaped electrode |
| 1915a, 1915b, 2015a, 2015b, 2015a′, | |
| 2015b′, 2115a, 2115b, 2515a, 2515b | |
| 16, 816, 1816, 1916, 2016, 2016′, | lower electrode |
| 2116, 2516 | |
| 17, 1817, 1917, 2017, 2017′ | slit |
| 18a, 18b, 818a, 818b, 2118a, 2118b, | glass substrate |
| 2518a, 2518b | |
| 19a, 19b, 819a, 819b, 2119a, 2119b, | insulating layer |
| 2519a, 2519b | |
| 20, 820, 2120, 2520 | opposite electrode |
| 21, 821, 2121, 2521 | liquid crystal layer |
| 22, 822, 2122, 2522 | liquid crystal molecule |
| 23, 823, 2123, 2523 | lower substrate |
| 24, 824, 2124, 2524 | upper substrate |
| 25, 825, 2125, 2525 | liquid crystal display panel |
| 422, 922, 1422, 1722, 2322, 2422 | director |
| 426, 926, 1426, 1726, 2326, 2426 | electric field distribution |
| | (equipotential line) |
| 427, 927, 1427, 1727, 2327, 2427 | transmittance distribution |
| TFT | thin film transistor |
| CF | color filter |

1: A liquid crystal display device, comprising:
a first substrate;
a second substrate facing said first substrate; and
a liquid crystal layer enclosed between said first substrate and said second substrate;
wherein said first substrate has a first electrode, a second electrode, and a third electrode, said third electrode being in a layer below the first electrode and the second electrode,
wherein said second substrate has a fourth electrode,
wherein said first electrode and said second electrode are a pair of comb-shaped electrodes that include a plurality of fingers and are provided on a liquid crystal layer side of said third electrode so as to at least partially overlap said third electrode on the first substrate,
wherein said third electrode has an opening,
wherein said fourth electrode is a planar electrode, and
wherein, in a plan view of a main surface of either substrate, an amount of overlap between said third electrode and a region between a finger of said first electrode and a finger adjacent thereto of said second electrode differs within a pixel.

2: The liquid crystal display device according to claim 1, wherein liquid crystal molecules contained in said liquid crystal layer are aligned perpendicularly to the main surface of either substrate when no voltage is applied thereto.

3: The liquid crystal display device according to claim 1,
wherein said liquid crystal display device includes a first region and a second region within a pixel,
wherein said first region is between a finger of said first electrode and a finger adjacent thereto of said second electrode,
wherein said first region entirely overlaps said third electrode,
wherein said second region is between a finger of said first electrode and a finger adjacent thereto of said second electrode,
wherein said second region does not overlap said third electrode, and
wherein an area ratio of said first region to said second region is 1:1.

4: The liquid crystal display device according to claim 1,
wherein said liquid crystal display device includes a first region and a third region within a pixel,
wherein said first region is between a finger of said first electrode and a finger adjacent thereto of said second electrode,
wherein said first region entirely overlaps said third electrode,
wherein said third region is between a finger of said first electrode and a finger adjacent thereto of said second electrode,
wherein said third region partially overlaps said third electrode, and
wherein an area ratio of said first region to said third region is 1:1.

5: The liquid crystal display device according to claim 1,
wherein at least one of said first substrate and said second substrate is provided with a thin film transistor element, and
wherein said thin film transistor element includes an oxide semiconductor.

6: The liquid crystal display device according to claim 2,
wherein said liquid crystal display device includes a first region and a second region within a pixel,
wherein said first region is between a finger of said first electrode and a finger adjacent thereto of said second electrode,
wherein said first region entirely overlaps said third electrode,
wherein said second region is between a finger of said first electrode and a finger adjacent thereto of said second electrode,
wherein said second region does not overlap said third electrode, and
wherein an area ratio of said first region to said second region is 1:1.

7: The liquid crystal display device according to claim 2,
wherein said liquid crystal display device includes a first region and a third region within a pixel,
wherein said first region is between a finger of said first electrode and a finger adjacent thereto of said second electrode,
wherein said first region entirely overlaps said third electrode,
wherein said third region is between a finger of said first electrode and a finger adjacent thereto of said second electrode,
wherein said third region partially overlaps said third electrode, and
wherein an area ratio of said first region to said third region is 1:1.

8: The liquid crystal display device according to claim 2,
wherein at least one of said first substrate and said second substrate is provided with a thin film transistor element, and
wherein said thin film transistor element includes an oxide semiconductor.

9: The liquid crystal display device according to claim 3,
wherein at least one of said first substrate and said second substrate is provided with a thin film transistor element, and
wherein said thin film transistor element includes an oxide semiconductor.

10: The liquid crystal display device according to claim 6,
wherein at least one of said first substrate and said second substrate is provided with a thin film transistor element, and
wherein said thin film transistor element includes an oxide semiconductor.

11: The liquid crystal display device according to claim 4,
wherein at least one of said first substrate and said second substrate is provided with a thin film transistor element, and
wherein said thin film transistor element includes an oxide semiconductor.

12: The liquid crystal display device according to claim 7,
wherein at least one of said first substrate and said second substrate is provided with a thin film transistor element, and
wherein said thin film transistor element includes an oxide semiconductor.

13: The liquid crystal display device according to claim 5, wherein said oxide semiconductor is formed of indium, gallium, zinc, and oxygen.

14: The liquid crystal display device according to claim 8, wherein said oxide semiconductor is formed of indium, gallium, zinc, and oxygen.

15: The liquid crystal display device according to claim 9, wherein said oxide semiconductor is formed of indium, gallium, zinc, and oxygen.

16: The liquid crystal display device according to claim 10, wherein said oxide semiconductor is formed of indium, gallium, zinc, and oxygen.

17: The liquid crystal display device according to claim 11, wherein said oxide semiconductor is formed of indium, gallium, zinc, and oxygen.

18: The liquid crystal display device according to claim 12, wherein said oxide semiconductor is formed of indium, gallium, zinc, and oxygen.
